(19) United States
(12) Patent Application Publication
(10) Pub. No.: US 2026/0231440 A1
(43) Pub. Date: Aug. 6, 2026

(54) SEMICONDUCTOR MEMORY DEVICE

(71) Applicant: Samsung Electronics Co., Ltd., Suwon-si (KR)

(72) Inventor: Jeon Il LEE, Suwon-si (KR)

(21) Appl. No.: 19/425,431

(22) Filed: Dec. 18, 2025

(30) Foreign Application Priority Data
Feb. 5, 2025 (KR) 10-2025-0014271

(51) Int. Cl. H10B 80/00; H10B 12/00; H10W 90/00

(52) U.S. Cl. CPC H10B 80/00; H10B 12/30; H10B 12/50; H10W 90/792

(57) ABSTRACT

A semiconductor memory device includes: a first cell structure including first local bitlines extending in a vertical direction, first memory cells connected to the respective first local bitlines, first local bitline multiplexers connected to the respective first local bitlines, and first global bitlines connected to the respective first local bitline multiplexers; a second cell structure on the first cell structure and including second local bitlines, second memory cells connected to the respective second local bitlines, second local bitline multiplexers connected to the respective second local bitlines, and second global bitlines connected to the second local bitline multiplexers; bitline contacts extending into the second cell structure and connecting the respective first global bitlines and the respective second global bitlines; and a peripheral circuit structure on the second cell structure and including a sense amplifier connected to the bitline contacts, where the first global bitlines and the second global bitlines share the sense amplifier.

### CROSS-REFERENCE TO RELATED APPLICATION

This application claims priority from Korean Patent Application No. 10-2025-0014271 filed on Feb. 5, 2025 in the Korean Intellectual Property Office, and all the benefits accruing therefrom under 35 U.S.C. 119, the contents of which in its entirety are herein incorporated by reference.

### BACKGROUND

To meet consumer demands for superior performance at a lower cost, increasing the integration density of semiconductor memory devices may be desired. In the case of semiconductor memory devices, integration density may be a factor in determining product cost, making higher integration density particularly desirable.

### SUMMARY

For conventional two-dimensional (2D) or planar semiconductor memory devices, integration density may be determined by the area occupied by a unit memory cell, which is largely influenced by the level of fine pattern formation technology. However, achieving finer patterns may entail the use of expensive equipment, which may increase integration density of 2D semiconductor memory devices increase, but achievable integration density still remains limited. Accordingly, three-dimensional (3D) semiconductor memory devices including memory cells arranged three-dimensionally have been proposed.

The present disclosure provides a semiconductor memory device including cell structures, each cell structure including local bitline multiplexers and sharing a sense amplifier.

The objectives of the present disclosure are not limited to those mentioned herein, and other objectives not explicitly stated will be clearly understood by those skilled in the art based on the following description.

An aspect of the present disclosure provides a semiconductor memory device including a first cell structure including first local bitlines extending in a vertical direction, first memory cells connected to the respective first local bitlines and arranged in the vertical direction, first local bitline multiplexers electrically connected to the respective first local bitlines, and first global bitlines electrically connected to the respective first local bitline multiplexers; a second cell structure on the first cell structure, the second cell structure including second local bitlines extending in the vertical direction, second memory cells connected to the respective second local bitlines and arranged in the vertical direction, second local bitline multiplexers electrically connected to the respective second local bitlines, and second global bitlines electrically connected to the second local bitline multiplexers; bitline contacts penetrating the second cell structure and electrically connecting the respective first global bitlines and the respective second global bitlines; and a peripheral circuit structure on the second cell structure, the peripheral circuit structure including a sense amplifier electrically connected to the bitline contacts, wherein the first global bitlines and the second global bitlines share the sense amplifier.

Another aspect of the present disclosure provides a semiconductor memory device including a first cell structure including a first local bitline extending in a vertical direction on a first insulating layer, first cell semiconductor patterns arranged in the vertical direction and each having a first end connected to the first local bitline, first data storage devices connected to second ends of the first cell semiconductor patterns, first cell gate electrodes on the first cell semiconductor patterns, a first logic semiconductor pattern spaced apart in the vertical direction from the first cell semiconductor patterns, a first logic transistor on the first logic semiconductor pattern and electrically connected to the first local bitline, and a first global bitline electrically connected to the first logic transistor; a second cell structure including a second local bitline extending in the vertical direction on a second insulating layer, second cell semiconductor patterns arranged in the vertical direction and each having a first end connected to the second local bitline, second data storage devices connected to second ends of the second cell semiconductor patterns, second cell gate electrodes on the second cell semiconductor patterns, a second logic semiconductor pattern spaced apart in the vertical direction from the second cell semiconductor patterns, a second logic transistor on the second logic semiconductor pattern and electrically connected to the second local bitline, and a second global bitline electrically connected to the second logic transistor; a bitline contact penetrating the second cell structure and electrically connecting the first global bitline and the second global bitline; and a peripheral circuit structure including a peripheral circuit substrate and a peripheral circuit transistor positioned on the peripheral circuit substrate and electrically connected to the first and second global bitlines.

Another aspect of the present disclosure provides a semiconductor memory device including a first cell structure including first local bitlines extending in a vertical direction, first memory cells arranged in the vertical direction and connected to the respective first local bitlines, first global bitlines on the first memory cells, first local bitline multiplexers electrically connected to the first global bitlines and the first local bitlines, and first global bitline multiplexers electrically connected to the first global bitlines; a second cell structure including second local bitlines extending in the vertical direction, second memory cells arranged in the vertical direction and connected to the respective second local bitlines, second global bitlines on the second memory cells, second local bitline multiplexers electrically connected to the second global bitlines and the second local bitlines, and second global bitline multiplexers electrically connected to the second global bitlines; and a peripheral circuit structure positioned on the second cell structure and including a sense amplifier electrically connected to the first global bitlines and the second global bitlines.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary implementations thereof in detail with reference to the attached drawings, in which:

FIG. 1 is a plan view of an example of a semiconductor memory device.

FIG. 2 is a cross-sectional view taken along I-I′ of FIG. 1.

FIG. 3 is a cross-sectional view taken along II-II′ of FIG. 1.

FIG. 4 is a cross-sectional view of an example of a semiconductor memory device.

FIG. 5 is a cross-sectional view of an example of a semiconductor memory device.

FIG. 6 is a cross-sectional view taken along I-I′ of FIG. 5;

FIG. 7 is an enlarged cross-sectional view of areas A1 and A2 in FIG. 6;

FIG. 8 is a cross-sectional view taken along I-I′ of FIG. 5;

FIGS. 9 and 10 are cross-sectional views of examples of semiconductor memory devices.

FIGS. 11-13 are plan views of examples of semiconductor memory devices.

FIGS. 14-37 are diagrams illustrating intermediate steps of a method for fabricating an example of a semiconductor memory device.

### DETAILED DESCRIPTION

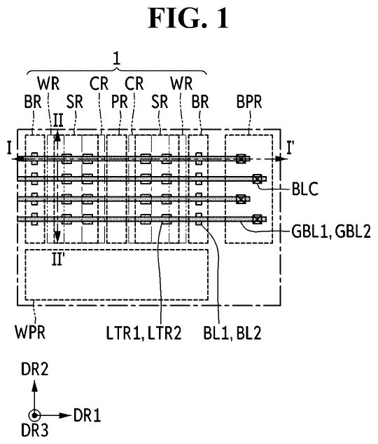

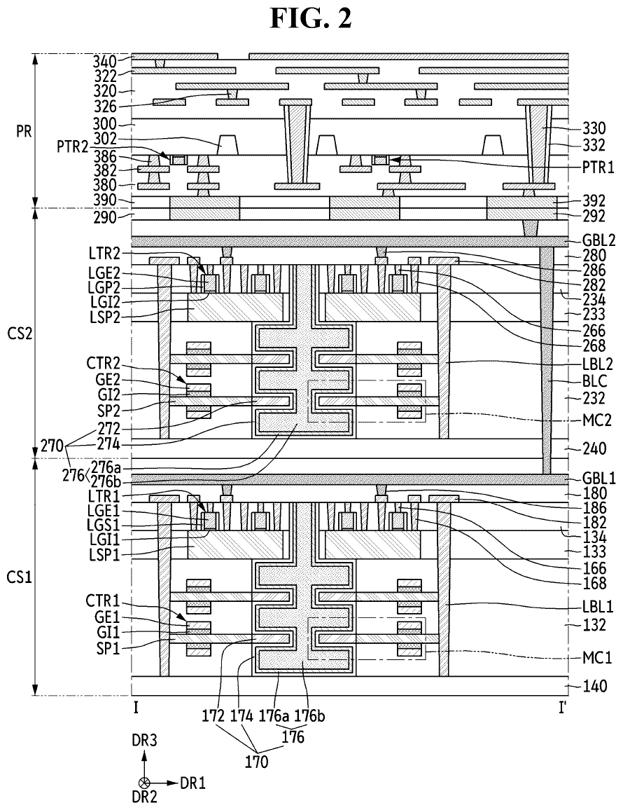

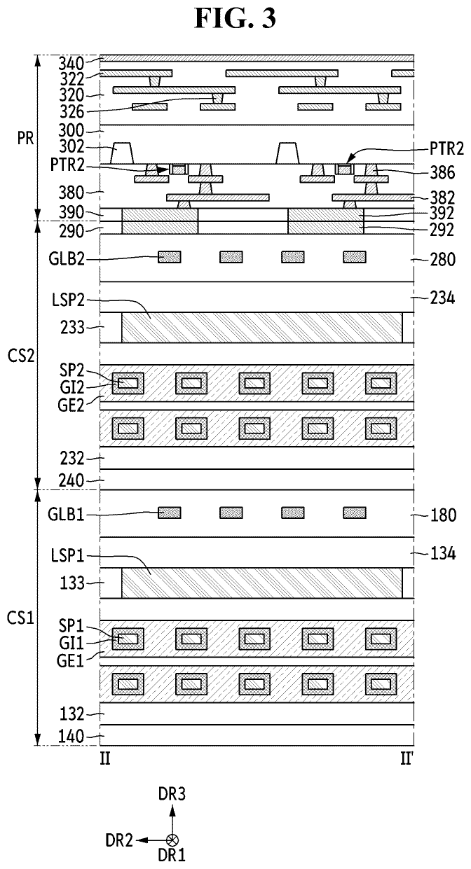

FIG. 1 is a plan view of a semiconductor memory device according to some implementations. FIG. 2 is a cross-sectional view taken along I-I′ of FIG. 1. FIG. 3 is a cross-sectional view taken along II-II′ of FIG. 1.

A first direction DR1 and a second direction DR2 may be parallel to the front surface of a first insulating layer 140, which will be described later, and may intersect each other (e.g., perpendicularly). A third direction DR3 may be perpendicular to the front surface of the first insulating layer 140 and may be perpendicular to the first and second directions DR1 and DR2. The third direction DR3 may be referred to as a vertical direction, the first direction DR1 may be referred to as a first horizontal direction, and the second direction DR2 may be referred to as a second horizontal direction. The front surface of the first insulating layer 140 may refer to the surface of the first insulating layer 140 where first memory cells MC1, which will be described later, are arranged.

Referring to FIGS. 1 and 2, the semiconductor memory device according to some implementations may include a cell region 1, a wordline pad region WPR, and a bitline pad region BPR.

The cell region 1 may include one or more bitline regions BR, one or more semiconductor regions SR, one or more wordline regions WR, one or more capacitor regions CR, and a plate region PR. The wordline regions WR may be positioned between the bitline regions BR and the capacitor regions CR. For example, the bitline regions BR, the wordline regions WR, and the capacitor regions CR may be arranged along the first direction DR1. The plate region PR may be positioned on a side of each of the capacitor regions CR. At least portions of the semiconductor regions SR may overlap the capacitor regions CR. At least portions of the semiconductor regions SR may overlap the wordline regions WR.

The wordline pad region WPR may be positioned on at least one side of the cell region 1. For example, the cell region 1 may be adjacent to the wordline pad region WPR in the second direction DR2. The wordline pad region WPR is illustrated as being spaced apart from the wordline regions WR, only for distinguishing these regions, and may be connected to the wordline regions WR. In some implementations, the semiconductor device may include a plurality of wordline pad regions WPR. For example, the plurality of wordline pad regions WPR may be positioned on both sides of the cell region 1 in the second direction DR2.

The semiconductor memory device according to some implementations may include a plurality of bitline regions BR, a plurality of wordline regions WR, and a plurality of capacitor regions CR. The bitline regions BR, the wordline regions WR, the semiconductor regions SR, and the capacitor regions CR may be symmetrically arranged with respect to the plate region PR. In some implementations, the semiconductor memory device may include a plurality of plate regions PR. In this case, on both sides of each of the plurality of plate regions PR, the bitline regions BR, the semiconductor regions SR, the wordline regions WR, and the capacitor regions CR may be symmetrically arranged with respect to the corresponding plate region PR. The capacitor regions CR are illustrated as being spaced apart from the plate region PR, only for distinguishing these regions, and the plate region PR may be connected to the capacitor regions CR located on either side thereof.

The semiconductor memory device according to some implementations may include first and second cell structures CS1 and CS2 and a peripheral circuit structure PR.

The first cell structure CS1 may include the first insulating layer 140, first local bitlines LBL1, first memory cells MC1, a first wiring insulating layer 180, first wirings 182, first vias 186, first global bitlines GBL1, and first logic transistors LTR1.

The first local bitlines LBL1 may be positioned in the respective bitline regions BR. The first local bitlines LBL1 may be spaced apart from each other in the second direction DR2 within the respective bitline regions BR. The first local bitlines LBL1 may each extend in the third direction DR3.

First memory cells MC1 arranged in the third direction DR3 may be connected to the respective first local bitlines LBL1. The first memory cells MC1 arranged in the third direction DR3 may be commonly connected to a first local bitline LBL1. The first memory cells MC1 may be spaced apart from each other in the first and second directions DR2 within a single layer. Adjacent first memory cells MC1 in the first direction DR1 may have a symmetric structure with respect to a vertical portion of a second conductive layer 176b that extends in the third direction DR3. Contrary to what is illustrated, in some implementations, the adjacent first memory cells MC1 in the first direction DR1, which have a symmetric structure with respect to the vertical portion of the second conductive layer 176b, may also be spaced apart from each other in the first direction DR1.

The first memory cells MC1 may each include a first cell transistor CTR1 and a first data storage device 170 that are connected to each other.

The first cell transistors CTR1 may each include a first cell semiconductor pattern SP1, a first cell gate electrode GE1, and a first cell gate insulating film GI1.

The first cell semiconductor patterns SP1 may be stacked in the third direction DR3 while being spaced apart from each other on the first insulating layer 140. The first local bitlines LBL1 may each be connected to a stack of first cell semiconductor patterns SP1 in the third direction DR3. The first cell semiconductor patterns SP1 may each extend in the first direction DR1. Stacks of first cell semiconductor patterns SP1 in the third direction DR3 may be arranged in the first and second directions DR1 and DR2.

The first cell semiconductor patterns SP1 may each include a first source/drain region, a second source/drain region, and a channel region between the first and second source/drain regions. First ends of the first cell semiconductor patterns SP1 in the first direction DR1 may correspond to first source/drain regions, and second ends of the first cell semiconductor patterns SP1 in the first direction DR1 may correspond to second source/drain regions. The first source/drain regions and the second source/drain regions may be regions doped with n-type or p-type impurities. The first ends of the first cell semiconductor patterns SP1 in the first direction DR1 may be connected to the first local bitlines LBL1, and the second ends of the first cell semiconductor patterns SP1 in the first direction DR1 may be connected to the first data storage devices 170.

The first cell gate electrodes GE1 may be positioned in the respective wordline regions WR. The first cell gate electrodes GE1 may be stacked in the third direction DR3 while being spaced apart from each other. The first cell gate electrodes GE1 may be positioned on at least portions of the outer circumferential surfaces of the respective first cell semiconductor patterns SP1. The first cell gate electrodes GE1 may each extend in the second direction DR2. The first cell gate electrodes GE1 may extend in the second direction DR2 while crossing the first semiconductor patterns SP1 within a single layer.

The first cell gate insulating films GI1 may be positioned between the first cell gate electrodes GE1 and the first cell semiconductor patterns SP1. The first cell gate electrodes GE1 may be spaced apart from the first cell semiconductor patterns SP1 by the first cell gate insulating films GI1.

A first cell insulating layer 132 may be positioned on the first insulating layer 140. The first cell insulating layer 132 may be positioned between the first cell semiconductor patterns SP1 and between the first cell gate electrodes GE1.

The first data storage devices 170 may be arranged in the capacitor regions CR and the plate region PR. The first data storage devices 170 may be positioned on the first cell semiconductor patterns SP1 and the first cell insulating layer 132. The first data storage devices 170 and the first local bitlines LBL1 may be positioned at opposite ends of the first cell semiconductor patterns SP1 in the first direction DR1.

The first data storage devices 170 and second data storage devices 270, which will be described later, may be capacitors or variable resistors. The first data storage devices 170 and the second data storage devices 270 will hereinafter be described as capacitors by way of example. The first data storage devices 170 may each include first storage electrodes 172, a first plate electrode 176, and a first dielectric layer 174 between the first storage electrodes 172 and the first plate electrode 176. Each of the first data storage devices 170 may be defined by the respective first storage electrodes 172.

The first storage electrodes 172 may be in contact with ends of the first cell semiconductor patterns SP1. For example, the lengths of the first storage electrodes 172 in the second and third directions DR2 and DR3 may be the same as the lengths of the first cell semiconductor patterns SP1 in the second and third directions DR2 and DR3, respectively.

The first dielectric layers 174 may cover the entire surfaces of the first storage electrodes 172 except for portions that are in contact with the first cell semiconductor patterns SP1. The first dielectric layers 174 may extend along the upper surfaces and lower surfaces of the first storage electrodes 172, as well as along the side surfaces of the first storage electrodes 172 that face the first plate electrodes 176. The first dielectric layers 174 may extend along the upper surface of the first insulating layer 140 and the side surface of the first cell insulating layer 132 between adjacent first storage electrodes 172 in the third direction DR3.

The first plate electrodes 176 may each include a first conductive layer 176a and a second conductive layer 176b. The first conductive layers 176a may be positioned on the respective first dielectric layers 174. The first conductive layers 176a may extend along the first dielectric layers 174. The second conductive layers 176b may be positioned on the first conductive layers 176a. The second conductive layers 176b may each include a vertical portion perpendicular to the upper surface of the first insulating layer 140 and horizontal portions parallel to the upper surface of the first insulating layer 140. The horizontal portions of the second conductive layers 176b may protrude in the first direction DR1 from the vertical portions of the second conductive layers 176b and may be surrounded by the first dielectric layers 174 and the first conductive layers 176a. The vertical portions of the second conductive layers 176b may be arranged in the plate region PR.

The first logic transistors LTR1 may be positioned on the first memory cells MC1. In some implementations, the first logic transistors LTR1 may be formed on the first cell insulating layer 132. The first logic transistors LTR1 may each include a first logic semiconductor pattern LSP1, a first logic gate electrode LGE1, a first logic gate insulating film LGI1, and first logic gate spacers LGS1.

The first logic semiconductor patterns LSP1 may be arranged in the respective semiconductor regions SR. The first logic semiconductor patterns LSP1 and first insulating patterns 133 may be positioned on the first cell insulating layer 132. The first logic semiconductor patterns LSP1 may be defined by the first insulating patterns 133. The first logic semiconductor patterns LSP1 may be spaced apart from each other by the first insulating patterns 133.

The first logic semiconductor patterns LSP1 may include the same material as the first cell semiconductor patterns SP1. In the third direction DR3, the thickness of the first logic semiconductor patterns LSP1 may be greater than the thickness of the first cell semiconductor patterns SP1.

The first logic gate electrodes LGE1 may be positioned on the first logic semiconductor patterns LSP1. The first logic gate insulating films LGI1 may be positioned between the first logic semiconductor patterns LSP1 and the first logic gate electrodes LGE1. The first logic gate spacers LGS1 may be positioned on the sidewalls of the first logic gate electrodes LGE1 and the sidewalls of the first logic gate insulating films LGI1. The first source/drain regions and the second source/drain regions may be provided in the first logic semiconductor patterns LSP1 adjacent to both sides of the first logic gate electrodes LGE1.

A first interlayer insulating layer 134 may be positioned on the first logic semiconductor patterns LSP1 and the first insulating patterns 133. The first interlayer insulating layer 134 may cover the first logic transistors LTR1.

First logic gate contacts 166 may penetrate the first interlayer insulating layer 134 to contact the first logic gate electrodes LGE1. First source/drain contacts 168 may contact the first source/drain regions and second source/drain regions in the first logic semiconductor patterns LSP1 adjacent to both sides of the first logic gate electrodes LGE1.

The first local bitlines LBL1 may penetrate the first cell insulating layer 132, the first insulating patterns 133, and the first interlayer insulating layers 134. The first plate electrodes 176 and the first dielectric layers 174 may extend into the first insulating patterns 133 and the first interlayer insulating layer 134.

A first wiring insulating layer 180 may be positioned on the first interlayer insulating layer 134. The first wirings 182 and the first vias 186 may be arranged in the first interlayer insulating layer 134. The first wirings 182 and the first vias 186 may be electrically connected to the first logic gate contacts 166 and the first source/drain contacts 168. The numbers, arrangements, and interconnections of the first wirings 182 and the first vias 186 may vary.

The first global bitlines GBL1 may be arranged in the first wiring insulating layer 180. The first global bitlines GBL1 may be spaced apart in the second direction DR2. Each of the first global bitlines GBL1 may be electrically connected to multiple first local bitlines LBL1. Each of the first global bitlines GBL1 may extend in the first direction DR1 and be electrically connected to multiple first local bitlines LBL1 spaced apart in the first direction DR1. The first global bitlines GBL1 are illustrated as being in the uppermost layer of the first wiring insulating layer 180. In some implementations, the first wirings 182 and the first vias 186 may be positioned above the first global bitlines GBL1.

The first local bitlines LBL1 may be directly connected to the first memory cells MC1, and the first global bitlines GBL1 may be connected to the first local bitlines LBL1 through the first wirings 182, the first vias 186, and the first logic transistors LTR1.

One or more first logic transistors LTR1 may be connected between the first global bitlines GBL1 and the first local bitlines LBL1. For example, the first source/drain regions of the first logic transistors LTR1 may be connected to the first local bitlines LBL1 through the first source/drain contacts 168, the first vias 186, and the first wirings 182, while the second source/drain regions of the first logic transistors LTR1 may be connected to the first global bitlines GBL1 through the first source/drain contacts 168, the first vias 186, and the first wirings 182. The first logic transistors LTR1 may be configured to connect one or more selected first local bitlines LBL1 to the first global bitlines GBL1. The first logic transistors LTR1 may form first local bitline multiplexers. The first logic transistors LTR1 may be referred to as first local bitline multiplexers.

The second cell structure CS2 may be positioned on the first cell structure CS1. The second cell structure CS2 may include a second insulating layer 240, second local bitlines LBL2, second memory cells MC2, a second wiring insulating layer 280, second wirings 282, second vias 286, second global bitlines GBL 2, second logic transistors LTR2, a first bonding insulating layer 290, and first bonding pads 292.

The second insulating layer 240 may be positioned on the first cell structure CS1. The second insulating layer 240 may be positioned on the first wiring insulating layer 180. The first and second insulating layers 140 and 240 may each include silicon oxide, silicon nitride, silicon oxynitride, or a combination thereof.

The second local bitlines LBL2 may be positioned in the bitline regions BR. The second local bitlines LBL2 may be spaced apart from each other in the second direction DR2 within the bitline regions BR. The second local bitlines LBL2 may each extend in the third direction DR3. The second local bitlines LBL2 may overlap the first local bitlines LBL1 in the third direction DR3.

In some examples, the first local bitlines LBL1 and the second local bitlines LBL2 may each include at least one conductive material, such as a doped semiconductor material (e.g., doped silicon, doped silicon-germanium, doped germanium), a conductive metal nitride (e.g., titanium nitride, tantalum nitride), a metal (e.g., tungsten, titanium, tantalum), or a metal-semiconductor compound (e.g., tungsten silicide, cobalt silicide, titanium silicide).

Second memory cells MC2 arranged in the third direction DR3 may be connected to the respective second local bitlines LBL2. The second memory cells MC2 arranged in the third direction DR3 may be commonly connected to a second local bitline LBL2. The second memory cells MC2 may be spaced apart in the first and second directions DR1 and DR2 within a single layer. Adjacent second memory cells MC2 in the first direction DR1 may have a symmetric structure with respect to a vertical portion of a fourth conductive layer 276b. Contrary to what is illustrated, in some implementations, the adjacent second memory cells MC2 in the first direction DR1, which have a symmetric structure with respect to the vertical portion of the fourth conductive layer 276b, may be spaced apart from each other in the first direction DR1.

The second memory cells MC2 may each include a second cell transistor CTR2 and a second data storage device 270, which are connected to each other.

The second cell transistors CTR2 may each include a second cell semiconductor pattern SP2, a second cell gate electrode GE2, and a second cell gate insulating film GI2.

The second cell semiconductor patterns SP2 may be stacked in the third direction DR3 while being spaced apart on the second insulating layer 240. The second local bitlines LBL2 may each be connected to a stack of second cell semiconductor patterns SP2 in the third direction DR3. The second cell semiconductor patterns SP2 may extend in the first direction DR1. Stacks of the second cell semiconductor patterns SP2 in the third direction DR3 may be arranged in the first and second directions DR1 and DR2. The second cell semiconductor patterns SP2 may overlap the first cell semiconductor patterns SP1 in the third direction DR3.

The second cell semiconductor patterns SP2 may each include a first source/drain region, a second source/drain region, and a channel region between the first and second source/drain regions. First ends of the second cell semiconductor patterns SP2 in the first direction DR1 may correspond to first source/drain regions, and second ends of the second cell semiconductor patterns SP2 in the first direction DR1 may correspond to second source/drain regions. The first source/drain regions and the second source/drain regions may be regions doped with n-type or p-type impurities. The first ends of the second cell semiconductor patterns SP2 in the first direction DR1 may be connected to the second local bitlines LBL2, and the second ends of the second cell semiconductor patterns SP2 in the first direction DR1 may be connected to the second data storage devices 270.

The first cell semiconductor patterns SP1 and the second cell semiconductor patterns SP2 may each include at least one of a monocrystalline semiconductor, a polycrystalline semiconductor, an oxide semiconductor, and a 2D material. For example, the monocrystalline semiconductor may be monocrystalline silicon. The polycrystalline semiconductor may be polysilicon. In some examples, the oxide semiconductor may be selected from InGaZnO (IGZO), Sn—IGZO, InWO (IWO), InZnO (IZO), ZnSnO (ZTO), ZnO, yttrium-doped zinc oxide (YZO), InGaSiO (IGSO), InO, SnO, TiO, ZnON, MgZnO, ZrInZnO, HfInZnO, SnInZnO, AlSnInZnO, SiInZnO, AlZnSnO, GaZnSnO, or ZrZnSnO. In some implementations, the 2D semiconductor may include a transition metal dichalcogenide or a bipolar semiconductor material that utilizes both electrons and holes as driving charges. In some examples, the two-dimensional semiconductor material may be selected from MoS₂, MoSe₂, WS₂, NbS₂, TaS₂, ZrS₂, HfS₂, TcS₂, ReS₂, CuS₂, GaS₂, InS₂, SnS₂, GeS₂, PbS₂, WSe₂, NbSe₂, TaSe₂, ZrSe₂, HfSe₂, TcSe₂, ReSe₂, CuSe₂, GaSe₂, InSe₂, SnSe₂, GeSe₂, PbSe₂, MoTe₂, WTe₂, NbTe₂, TaTe₂, ZrTe₂, HfTe₂, TcTe₂, ReTe₂, CuTe₂, GaTe₂, InTe₂, SnTe₂, GeTe₂, or PbTe₂.

In some implementations, the first cell transistors CTR1 and the second cell transistors CTR2 may be gate-all-around transistors (GAA transistors). The first cell gate electrodes GE1 may surround the channel regions of the first cell semiconductor patterns SP1, and the second cell gate electrodes GE2 may surround the channel regions of the second cell semiconductor patterns SP2. The first cell gate electrodes GE1 may surround the outer circumferential surfaces of the channel regions of the first cell semiconductor patterns SP1, and the second cell gate electrodes GE2 may surround the outer circumferential surfaces of the channel region of the second cell semiconductor pattern SP2. The first cell gate electrode GE1 may extend in the second direction DR2 and surround the channel regions of first cell semiconductor patterns SP1 that are spaced apart in the second direction DR2 at the same height. The second cell gate electrodes GE2 may extend in the second direction DR2 and surround the channel regions of second cell semiconductor patterns SP2 that are spaced apart in the second direction DR2 at the same height.

Contrary to what is illustrated, in some implementations, the first cell transistors CTR1 and the second cell transistors CTR2 may each have a double-gate transistor structure. The first cell gate electrodes GE1 may be positioned on opposite sidewalls of the channel regions of the first cell semiconductor patterns SP1 (e.g., on opposite sidewalls in the third direction DR3) to be spaced apart from each other, and the second cell gate electrodes GE2 may be positioned on opposite sidewalls of the channel regions of the second cell semiconductor patterns SP2 (e.g., on opposite sidewalls in the third direction DR3) to be spaced apart from each other.

In some implementations, the first cell gate electrodes GE1 may each be positioned on one sidewall of the respective first cell semiconductor patterns SP1, and the second cell gate electrodes GE2 may be positioned on one sidewall of the respective second cell semiconductor patterns SP2.

In some examples, the first cell gate electrodes GE1 and the second cell gate electrodes GE2 may each include at least one conductive material, such as a doped semiconductor material, a conductive metal nitride, a metal, or a metal-semiconductor compound.

Cell gate contacts may be arranged in the wordline pad region WPR. The cell gate contacts may be in contact with the first or second cell gate electrodes GE1 or GE2.

Second cell gate insulating films GI2 may be positioned between the second cell gate electrodes GE2 and the second cell semiconductor patterns SP2. The second cell gate electrodes GE2 may be spaced apart from the second cell semiconductor patterns SP2 by the second cell gate insulating films GI2. The first cell gate insulating films GI1 and the second cell gate insulating films GI2 may each include, for example, at least one of a high-k insulating film, a silicon oxide film, a silicon nitride film, and a silicon oxynitride film.

A second cell insulating layer 232 may be positioned on the second insulating layer 240. The second cell insulating layer 232 may be positioned between the second cell semiconductor patterns SP2 and between the second cell gate electrodes GE2. The first and second cell insulating layers 132 and 232 may each include an insulating material, such as, for example, at least one of a silicon oxide film, a silicon nitride film, a silicon oxynitride film, a carbon-containing silicon oxide film, a carbon-containing silicon nitride film, or a carbon-containing silicon oxynitride film. For example, the first and second cell insulating layers 132 and 232 may each include a silicon oxide film.

The second data storage devices 270 may be arranged in the capacitor regions CR and the plate region PR. The second data storage devices 270 may be positioned on the second cell semiconductor patterns SP2 and the second cell insulating layer 232. The second data storage devices 270 and the second local bitlines LBL2 may be positioned at opposite ends of the second cell semiconductor patterns SP2 in the first direction DR1. The second data storage devices 270 may each include second storage electrodes 272, a second plate electrode 276, and a second dielectric layers 274 between the second storage electrodes 272 and the second plate electrode 276. Each of the second data storage devices 270 may be defined by the respective second storage electrodes 272.

The second storage electrodes 272 may be in contact with the second ends of the second cell semiconductor patterns SP2. For example, the lengths of the second storage electrodes 272 in the second and third directions DR3 may be the same as the lengths of the second cell semiconductor patterns SP2 in the second and third directions DR2 and DR3, respectively.

The second dielectric layers 274 may cover the entire surfaces of the second storage electrodes 272, except for portions that are in contact with the second cell semiconductor patterns SP2. The second dielectric layers 274 may extend along the upper surfaces and lower surfaces of the second storage electrodes 272, as well as along the side surfaces of the second storage electrodes 272 facing the second plate electrodes 276. The second dielectric layers 274 may extend along the upper surface of the second insulating layer 240 and the side surfaces of the second cell insulating layer 232 between adjacent second storage electrodes 272 in the third direction DR3.

The second plate electrodes 276 may each include a third conductive layer 276a and a fourth conductive layer 276b. The third conductive layers 276a may extend along the second dielectric layers 274. The fourth conductive layers 276b may be positioned on the respective third conductive layers 276a. The fourth conductive layers 276b may each include a vertical portion perpendicular to the upper surface of the second insulating layer 240 (e.g., in the third direction DR3) and horizontal portions parallel to the upper surface of the second insulating layer 240 (e.g., in the first direction DR1). The horizontal portions of the fourth conductive layers 276b may protrude in the first direction DR1 from the vertical portions of the fourth conductive layers 276b and may be surrounded by the second dielectric layers 274 and the third conductive layers 276a. The vertical portions of the fourth conductive layers 276b may be positioned in the plate region PR.

The first storage electrodes 172, the second storage electrodes 272, the first plate electrodes 176, and the second plate electrodes 276 may each include a conductive material. In some cases, the first storage electrodes 172, the second storage electrodes 272, the first plate electrodes 176, and the second plate electrodes 276 may each include, for example, at least one of a doped semiconductor material, a conductive metal nitride (e.g., titanium nitride, tantalum nitride, niobium nitride, or tungsten nitride), a metal (e.g., ruthenium, iridium, titanium, niobium, tungsten, cobalt, molybdenum, or tantalum), and a conductive metal oxide (e.g., iridium oxide or niobium oxide). For example, the first and third conductive layers 176a and 276a may each include the same material as the first storage electrodes 172 and the second storage electrodes 272, while the second and fourth conductive layers 176b and 276b may include a material different from the first and third conductive layers 176a and 276a, the first storage electrodes 172, and the second storage electrodes 272. In one example, the first storage electrodes 172 and the second storage electrodes 272, as well as the first and third conductive layers 176a and 276a, may include titanium nitride, while the second and fourth conductive layers 176b and 276b may include doped silicon-germanium.

The first and second dielectric layers 174 and 274 may each include, for example, a high-k material (e.g., hafnium oxide, hafnium silicon oxide, lanthanum oxide, zirconium oxide, zirconium silicon oxide, tantalum oxide, titanium oxide, barium strontium titanate, barium titanate, strontium titanate, lithium oxide, aluminum oxide, lead scandium tantalate, lead zinc niobate, or combinations thereof). In the semiconductor memory device according to some implementations, the first dielectric layers 174 may have a stacked structure where zirconium oxide, aluminum oxide, and zirconium oxide are sequentially stacked. In some implementations, the first dielectric layers 174 and the second dielectric layers 274 may each include hafnium (Hf).

The second logic transistors LTR2 may be positioned on the second memory cells MC2. In some implementations, the second logic transistors LTR2 may be formed on the second cell insulating layer 232. The second logic transistors LTR2 may each include a second logic semiconductor pattern LSP2, a second logic gate electrode LGE2, and a second logic gate insulating film LGI2.

Second logic semiconductor patterns LSP2 may be positioned in the respective semiconductor regions SR. The second logic semiconductor patterns LSP2 and second insulating patterns 233 may be positioned on the second cell insulating layer 232. The second logic semiconductor patterns LSP2 may be defined by the second insulating patterns 233. The second logic semiconductor patterns LSP2 may be spaced apart from each other by the second insulating patterns 233. The second logic semiconductor patterns LSP2 may overlap the first logic semiconductor patterns LSP1 in the third direction DR3.

The second logic semiconductor patterns LSP2 may include the same material as the second cell semiconductor patterns SP2. In the third direction DR3, the thickness of the second logic semiconductor patterns LSP2 may be greater than the thickness of the second cell semiconductor patterns SP2.

The second logic gate electrodes LGE2 may be positioned on the second logic semiconductor patterns LSP2. The second logic gate insulating films LGI2 may be positioned between the second logic semiconductor patterns LSP2 and the second logic gate electrodes LGE2. The second logic gate spacers LGS2 may be positioned on the sidewalls of the second logic gate electrodes LGE2 and the sidewalls of the second logic gate insulating films LGI2. First source/drain regions and second source/drain regions may be positioned in the second logic semiconductor patterns LSP2 adjacent to both sides of the second logic gate electrodes LGE2.

In some examples, the first logic gate electrodes LGE1 and the second logic gate electrodes LGE2 may each include at least one conductive material, such as a doped semiconductor material, a conductive metal nitride, a metal, or a metal-semiconductor compound. The first logic gate insulating films LGI1 and the second logic gate insulating films LGI2 may each include, for example, at least one of a high-k insulating film, a silicon oxide film, a silicon nitride film, and a silicon oxynitride film. The first logic gate spacers LGS1 and the second logic gate spacers LGS2 may each include, for example, at least one of a silicon oxide film, a silicon nitride film, or a silicon oxynitride film.

The second interlayer insulating layer 234 may be positioned on the second logic semiconductor patterns LSP2 and the second insulating patterns 233. The second interlayer insulating layer 234 may cover the second logic transistors LTR2.

Second logic gate contacts 266 may penetrate the second interlayer insulating layer 234 and be in contact with the second logic gate electrodes LGE2. Second source/drain contacts 268 may be in contact with the source/drain regions in the second logic semiconductor patterns LSP2 adjacent to both sides of the second logic gate electrodes LGE2.

The second local bitlines LBL2 may penetrate the second cell insulating layer 232, the second insulating patterns 233, and the second interlayer insulating layer 234. The second plate electrodes 276 and the second dielectric layers 274 may extend into the second insulating patterns 233 and the second interlayer insulating layer 234.

A second wiring insulating layer 280 may be positioned on the second cell insulating layer 232. The second wirings 282 and the second vias 286 may be positioned within the second cell insulating layer 232. The second wirings 282 and the second vias 286 may be electrically connected to the second logic gate contacts 266 and the second source/drain contacts 268. The numbers, arrangements, and interconnections of the second wirings 282 and the second vias 286 may vary.

The second global bitlines GBL2 may be positioned in the second wiring insulating layer 280. The second global bitlines GBL2 may be spaced apart in the second direction DR2. Each of the second global bitlines GBL2 may be electrically connected to multiple second local bitlines LBL2. Each of the second global bitlines GBL2 may extend in the first direction DR1 and be electrically connected to multiple second local bitlines LBL2 spaced apart in the first direction DR1. The second global bitlines GBL2 are illustrated as being in the uppermost layer of the second wiring insulating layer 280. In some implementations, the second wirings 282 and the second vias 286 may be positioned above the second global bitlines GBL2.

The second local bitlines LBL2 may be directly connected to the second memory cells MC2, and the second global bitlines GBL2 may be connected to the second local bitlines LBL2 via the second wirings 282, the second vias 286, and the second logic transistors LTR2.

In some examples, the first global bitlines GBL1 and the second global bitlines GBL2 may each include a conductive material, such as a doped semiconductor material (e.g., doped silicon, doped silicon-germanium, doped germanium), a conductive metal nitride (e.g., titanium nitride, tantalum nitride), a metal (e.g., tungsten, titanium, tantalum), or a metal-semiconductor compound (e.g., tungsten silicide, cobalt silicide, titanium silicide).

One or more second logic transistors LTR2 may be connected between the second global bitlines GBL2 and the second local bitlines LBL2. For example, the first source/drain regions of the second logic transistors LTR2 may be connected to the second local bitlines LBL2 via the second source/drain contacts 268, the second vias 286, and the second wirings 282, while the second source/drain regions of the second logic transistors LTR2 may be connected to the second global bitlines GBL2 via the second source/drain contacts 268, the second vias 286, and the second wirings 282. The second logic transistors LTR2 may be configured to connect one or more selected second local bitlines LBL2 to the second global bitlines GBL2. The second logic transistors LTR2 may form second local bitline multiplexers and may be referred to as second local bitline multiplexers.

The bitline pad region BPR may be positioned on at least one side of the cell region 1. In some implementations, the bitline pad region BPR may be positioned on one side of the cell region 1 in the first direction DR1. The cell region 1 and the bitline pad region BPR may be adjacent in the first direction DR1. Bitline contacts BLC may be positioned in the bitline pad region BPR.

In some implementations, the bitline contacts BLC may be arranged in a zigzag fashion along the second direction DR2 in the bitline pad region BPR. In some examples, each of the bitline contacts BLC may alternately offset adjacent bitline contact along the second direction DR2 in the bitline pad region BPR.

The bitline contacts BLC may extend in the third direction DR3. The bitline contacts BLC may extend in the third direction DR3 through the second wiring insulating layer 280, the second interlayer insulating layer 234, the second insulating patterns 233, the second cell insulating layer 232, the second insulating layer 240, and the first wiring insulating layer 180. The bitline contacts BLC may electrically connect the first global bitlines GBL1 and the second global bitlines GBL2.

The first bonding insulating film 290 may be positioned on the second wiring insulating layer 280. The first bonding pads 292 may be positioned in the first bonding insulating film 290. The first bonding pads 292 may be connected to the second vias 286. The first bonding pads 292 may be electrically connected to the second wirings 282 and the second vias 286. The first bonding pads 292 may be electrically connected to the second global bitlines GBL2.

In some implementations, the first and second cell structures CS1 and CS2 may be bonded to each other by bonding the first and second insulating layers 140 and 240. The first and second insulating layers 140 and 240 may be in contact with each other. In some implementations, the bitline contacts BLC may be in contact with the respective first global bitlines GBL1 and the respective second global bitlines GBL2. The first logic transistors LTR1 and the first global bitlines GBL1 may be positioned between the first memory cells MC1 and the second cell structure CS2, while the second logic transistors LTR2 and the second global bitlines GBL2 may be positioned between the second memory cells MC2 and the first cell structure CS1.

The peripheral circuit structure PR may be positioned on the second cell structure CS2. The peripheral circuit structure PR may include a substrate 300, peripheral circuit transistors (PTR1 and PTR2), a front insulating layer 380, front wirings 382, front vias 386, a second bonding insulating film 390, second bonding pads 392, a rear insulating layer 320, rear wirings 322, rear vias 326, external connection pads 340, and through vias 330.

The substrate 300 may include a front side and a rear side in the third direction DR3. The substrate 300 may include a semiconductor substrate such as a silicon substrate, a germanium substrate, or a silicon-germanium substrate. Alternatively, the substrate 300 may include a silicon-on-insulator (SOI) substrate or a germanium-on-insulator (GOI) substrate.

Device isolation patterns 302 may be formed in the substrate 300. The device isolation patterns 302 may be embedded in the front side of the substrate 300. The peripheral circuit transistors (PTR1 and PTR2) may be positioned on the front side of the substrate 300. The peripheral circuit transistors (PTR1 and PTR2) may be positioned on active regions defined by the device isolation pattern 302.

First peripheral circuit transistors PTR1 may form sense amplifiers and may be referred to as sense amplifiers. The first peripheral circuit transistors PTR1 may be configured to detect and amplify data from the first local bitlines LBL1 and the second local bitlines LBL2. Second peripheral circuit transistors PTR2 may be transistors forming various circuits for controlling the first memory cells MC1 and the second memory cells MC2. For example, the second peripheral circuit transistors PTR2 may be transistors forming sub-wordline drivers that provide voltage to the first cell gate electrodes GE1 and the second cell gate electrodes GE2.

The front insulating layer 380 may be positioned on the front side of the substrate 300. The front wirings 382 and the front vias 386 may be positioned in the front insulating layer 380. The front vias 386 may connect front wirings 382 positioned at different heights. The numbers, arrangements, and interconnections of the front wirings 382 and the front vias 386 may vary. The front wirings 382 and the front vias 386 may be electrically connected to the peripheral circuit transistors (PTR1 and PTR2). The front vias 386 may include vias connected to the source/drain regions and the gate electrodes of the peripheral circuit transistors (PTR1 and PTR2).

The second bonding insulating film 390 may be positioned on the front insulating layer 380. The second bonding pad 392 may be positioned in the second bonding insulating film 390. The second bonding pad 392 may be connected to the front vias 386. The second bonding pads 392 may be electrically connected to the front wirings 382 and the front vias 386.

In some implementations, the second cell structure CS2 and the peripheral circuit structure PR may have a chip-to-chip structure. After manufacturing the second cell structure CS2 and the peripheral circuit structure PR, the second cell structure CS2 and the peripheral circuit structure PR may be bonded together to fabricate the semiconductor memory device according to some implementations.

The first bonding pads 292 and the second bonding pads 392 may be bonded together. As a result of the bonding, the second cell structure CS2 and the peripheral circuit structure PR may be electrically connected. The first bonding pads 292 and the second bonding pads 392 may each include various metals, such as copper (Cu), aluminum (Al), or tungsten (W). The first and second bonding insulating films 290 and 390 may be bonded together. The first and second bonding insulating films 290 and 390 may each include an insulating material such as silicon oxide.

The rear insulating layer 320 may be positioned on the rear side of the substrate 300. The rear wirings 322 and the rear vias 326 may be positioned in the rear insulating layer 320. The rear vias 326 may connect rear wirings 322 positioned at different heights. The numbers, arrangements, and interconnections of the rear wirings 322 and the rear vias 326 may vary.

The through vias 330 may penetrate the rear insulating layer 320, the substrate 300, and the front insulating layer 380 to connect the rear wirings 322 and the front wirings 382. The through vias 330 may be in contact with the rear wirings 322 and the front wirings 382. Insulating spacers 332 may surround the sidewalls of the through vias 330.

External connection pads 340 may be positioned on the rear insulating layer 320. The external connection pads 340 may be connected to the rear wirings 322 and the rear vias 326.

In some implementations, the first and second cell structures CS1 and CS2 may share sense amplifiers, i.e., the first peripheral transistors PTR1. The first global bitlines GBL1 and the second global bitlines GBL2 may share the sense amplifiers. Accordingly, multiple global bitlines (GBL1 and GBL2) can be sensed simultaneously with a single sense amplifier.

Specifically, the first local bitlines LBL1 may be electrically connected to the first peripheral transistors PTR1 via the first logic transistors LTR1, the first global bitlines GBL1, and the bitline contacts BLC. The second local bitlines LBL2 may be electrically connected to the first peripheral transistors PTR1 via the second logic transistors LTR2 and the second global bitlines GBL2. The first local bitlines LBL1 and the second local bitlines LBL2 may be selected by the first logic transistors LTR1 and the second logic transistors LTR2 to be connected to the sense amplifiers. Accordingly, compared to a case where the first and second cell structures CS1 and CS2 include separate sets of sense amplifiers, the size of the semiconductor memory device according to some implementations can be reduced. Furthermore, the fabrication of a semiconductor memory device including multiple cell structures can be facilitated.

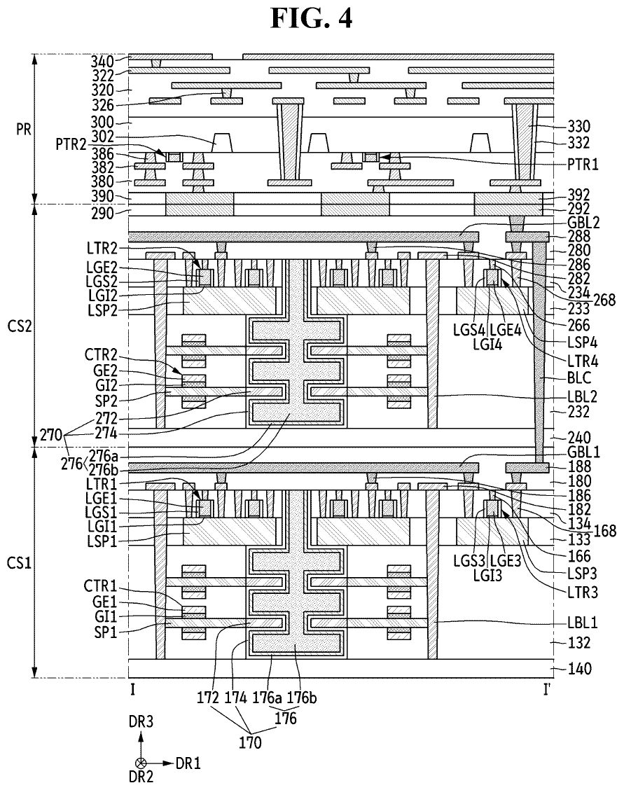

FIG. 4 is a cross-sectional view of a semiconductor memory device according to some implementations. FIG. 4 is a cross-sectional view taken along I-I′ of FIG. 1.

Referring to FIGS. 1 and 4, in some implementations, a first cell structure CS1 may further include third logic transistors LTR3, and a second cell structure CS2 may further include fourth logic transistors LTR4.

The third logic transistors LTR3 and the fourth logic transistors LTR4 may be positioned in a bitline pad region BPR. For example, the fourth logic transistors LTR4 may be positioned between adjacent second local bitlines LBL2 and bitline contacts BLC, and the third logic transistors LTR3 may be positioned below the fourth logic transistors LTR4 so as to overlap the fourth logic transistors LTR4 in the third direction DR3.

In some implementations, the third logic transistors LTR3 may be formed at the same height as first logic transistors LTR1, and the fourth logic transistors LTR4 may be formed at the same height as second logic transistors LTR2.

The third logic transistors LTR3 may be formed on a first cell insulating layer 132. The third logic transistors LTR3 may each include a third logic semiconductor pattern LSP3, a third logic gate electrode LGE3, a third logic gate insulating film LGI3, and third logic gate spacers LGS3.

Third logic semiconductor patterns LSP3 may be defined by first insulating patterns 133. The third logic semiconductor patterns LSP3 may be insulated from the first logic semiconductor patterns LSP1 by the first insulating patterns 133.

The third logic semiconductor patterns LSP3 may include the same material as first cell semiconductor patterns SP1. In the third direction DR3, the thickness of the third logic semiconductor patterns LSP3 may be substantially the same as the thickness of the first logic semiconductor patterns LSP1 and may be greater than the thickness of the first cell semiconductor patterns SP1.

Third logic gate electrodes LGE3 may be positioned on the third logic semiconductor patterns LSP3. The third logic gate insulating film LGI3 may be positioned between the third logic semiconductor patterns LSP3 and the third logic gate electrodes LGE3. The third logic gate spacers LGS3 may be positioned on the sidewalls of the third logic gate electrodes LGE3 and the sidewalls of the third logic gate insulating film LGI3. First source/drain regions and second source/drain regions may be positioned in the third logic semiconductor patterns LSP3 adjacent to both sides of the third logic gate electrodes LGE3.

A first interlayer insulating layer 134 may cover the third logic transistors LTR3. First logic gate contacts 166 may be in contact with the third logic gate electrodes LGE3, and first source/drain contacts 168 may be in contact with the first source/drain regions and second source/drain regions in the third logic semiconductor patterns LSP3 adjacent to both sides of the third logic gate electrodes LGE3.

One or more third logic transistors LTR3 may be connected between first global bitlines GBL1 and the bitline contacts BLC. For example, the first source/drain regions of the third logic transistors LTR3 may be connected to the first global bitlines GBL1 via the first source/drain contacts 168, first vias 186, and first wirings 182, while the second source/drain regions of the third logic transistors LTR3 may be connected to the bitline contacts BLC via first source/drain contacts 168, first vias 186, and first wirings 188 that are positioned at the same height as the first global bitlines GBL1. The third logic transistors LTR3 may be configured to connect one or more selected first global bitlines GBL1 to the bitline contacts BLC. The third logic transistors LTR3 may form first global bitline multiplexers and may be referred to as first global bitline multiplexers.

In some implementations, the first global bitline multiplexers do not overlap the first memory cells MC1 in the vertical direction. For instance, the first global bitline multiplexers are offset from the first memory cells MC1 in the vertical direction.

One or more fourth logic transistors LTR4 may be connected between second global bitlines GBL2 and the bitline contacts BLC. For example, the first source/drain regions of the fourth logic transistors LTR4 may be connected to the second global bitlines GBL2 via second source/drain contacts 268, second vias 286, and second wirings 282, while the second source/drain regions of the fourth logic transistors LTR4 may be connected to the bitline contacts BLC via second source/drain contacts 268, second vias 286, and second wirings 288 that are positioned at the same height as the second global bitlines GBL2. The fourth logic transistors LTR4 may be configured to connect one or more selected second global bitlines GBL2 to the bitline contacts BLC. The fourth logic transistors LTR4 may form second global bitline multiplexers and may be referred to as second global bitline multiplexers.

In some implementations, the second global bitline multiplexers do not overlap the second memory cells MC2 in the vertical direction. For instance, the second global bitline multiplexers are offset from the second memory cells MC2 in the vertical direction.

The bitline contacts BLC may be in contact with the first wirings 188 and the second wirings 288.

In the semiconductor memory device according to some implementations, sense amplifiers may sense the global bitlines (GBL1 and GBL2) of a selected cell structure CS1 or CS2 via the first global bitline multiplexers and the second global bitline multiplexers.

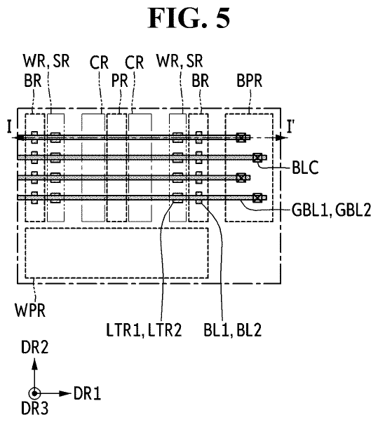

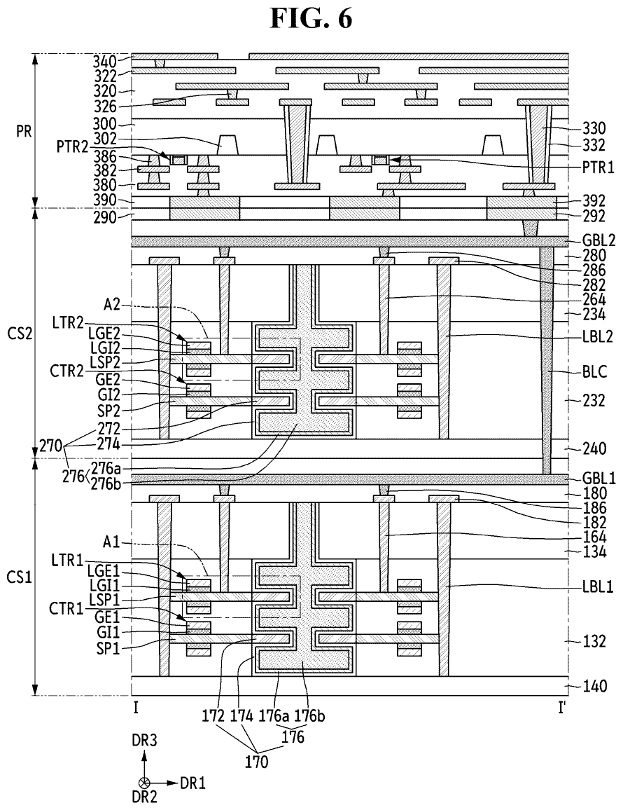

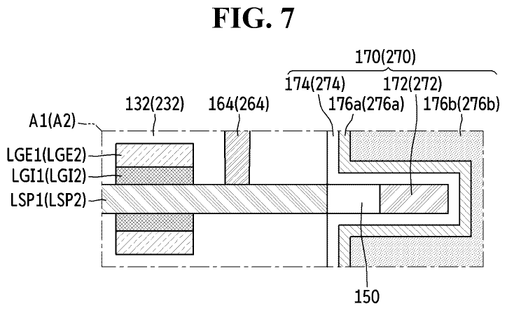

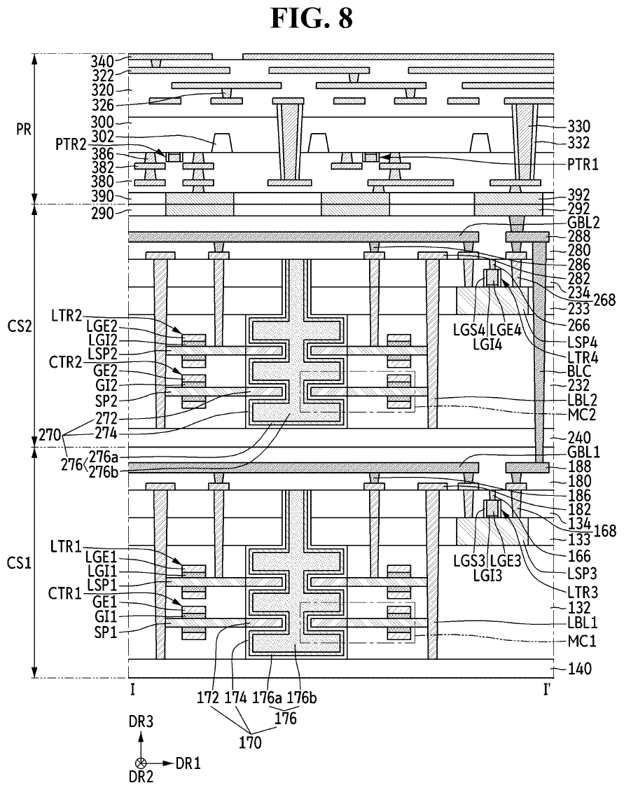

FIG. 5 is a cross-sectional view of a semiconductor memory device according to some implementations. FIGS. 6 and 8 are cross-sectional views taken along I-I′ of FIG. 5. FIG. 7 is an enlarged cross-sectional view of areas A1 and A2 in FIG. 6. For convenience, overlapping content with the descriptions of FIGS. 1 through 4 will be briefly described, while focusing on the differences.

Referring to FIGS. 5 through 8, in some implementations, first cell transistors CTR1 included in some first memory cells MC1 may be provided as first logic transistors LTR1, and second cell transistors CTR2 included in some second memory cells MC2 may be provided as second logic transistors LTR2. Semiconductor regions SR may overlap wordline regions WR.

Uppermost first cell transistors CTR1 may be provided as the first logic transistors LTR1. Uppermost first cell semiconductor patterns SP1 may be provided as first logic semiconductor patterns LSP1, and first cell gate electrodes GE1 and first cell gate insulating films GI1 on the uppermost first cell semiconductor patterns SP1 may be provided as first logic gate electrodes LGE1 and first logic gate insulating films LGI1, respectively. First ends of the first logic semiconductor patterns LSP1 in the first direction DR1 may be connected to first local bitlines LBL1.

Second cell transistors CTR2 of uppermost second memory cells MC2 may be provided as second logic transistors LTR2. Uppermost second cell semiconductor patterns SP2 may be provided as second logic semiconductor patterns LSP2, and second cell gate electrodes GE2 and second cell gate insulating films GI2 on the uppermost second cell semiconductor patterns SP2 may be provided as second logic gate electrodes LGE2 and second logic gate insulating films LGI2, respectively. First ends of the second logic semiconductor patterns LSP2 in the second direction DR2 may be connected to second local bitlines LBL2.

First source/drain contacts 164 may penetrate a first interlayer insulating layer 134 and a first cell insulating layer 132 to be in contact with the second source/drain regions of the first logic semiconductor patterns LSP1. Second source/drain contacts 268 may penetrate a second interlayer insulating layer 234 and a second cell insulating layer 232 to be in contact with the second source/drain regions of the second logic semiconductor patterns LSP2. Although not illustrated, logic gate contacts may be positioned in a wordline pad region WPR. The logic gate contacts may be in contact with the respective first or second logic gate electrodes LGE1 or LGE2.

In some implementations, second ends of the first logic semiconductor patterns LSP1 in the first direction DR1 and second ends of the second logic semiconductor patterns LSP2 in the first direction DR1 may be connected to first data storage devices 170 and second data storage devices 270, respectively. First storage electrodes 172 and second storage electrodes 272 may be in contact with the second ends of the first logic semiconductor patterns LSP1 and the second ends of the second logic semiconductor patterns LSP2, respectively. First ends of the first logic semiconductor patterns LSP1 in the first direction DR1 and first ends of the second logic semiconductor patterns LSP2 in the first direction DR2 may be in contact with the first logical bitlines LBL1 and the second logical bitlines LBL2, respectively.

Referring to FIG. 7, in some implementations, insulating patterns 150 may be positioned between the first logic semiconductor patterns LSP1 and the first data storage devices 170 and between the second logic semiconductor patterns LSP2 and the second data storage devices 270. The second ends of the first logic semiconductor patterns LSP1 in the first direction DR1 may be spaced apart from the first data storage devices 170, and the second ends of the second logic semiconductor patterns LSP2 in the first direction DR1 may be spaced apart from the second data storage devices 270. For example, the insulating patterns 150 may be positioned between the first logic semiconductor patterns LSP1 and the first storage electrodes 172 and between the second logic semiconductor patterns LSP2 and the second storage electrodes 272.

Referring to FIG. 8, in some implementations, a first cell structure CS1 may further include the third logic transistors LTR3, and a second cell structure CS2 may further include the fourth logic transistors LTR4.

In some implementations, the third logic transistors LTR3 may be formed at a different height than the first logic transistors LTR1, and the fourth logic transistors LTR4 may be formed at a different height than the second logic transistors LTR2. For example, the third logic transistors LTR3 may be formed above the first logic transistors LTR1 with respect to the front side of a first insulating layer 140 in which the first memory cells MC1 are formed, and the fourth logic transistors LTR4 may be formed above the second logic transistors LTR2 with respect to the front side of a second insulating layer 240 in which the second memory cells MC2 are formed.

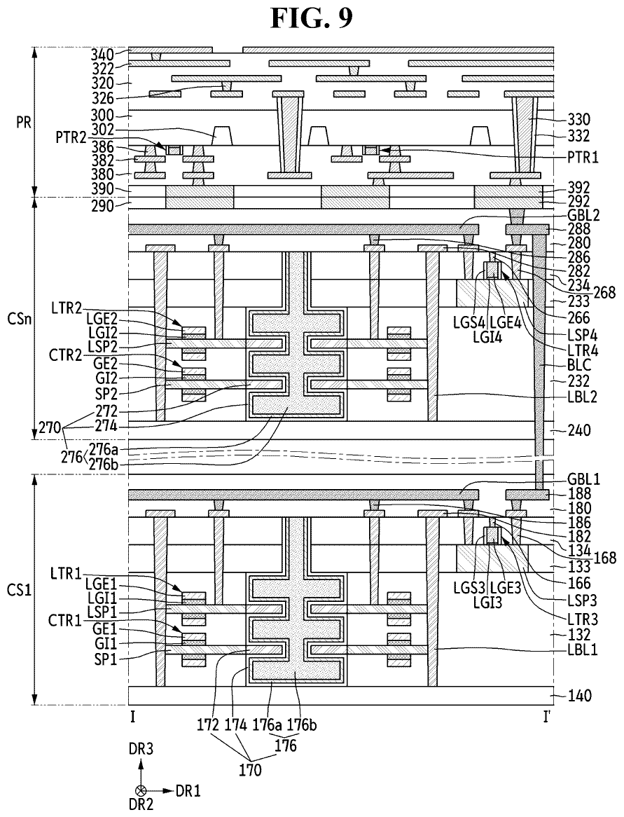

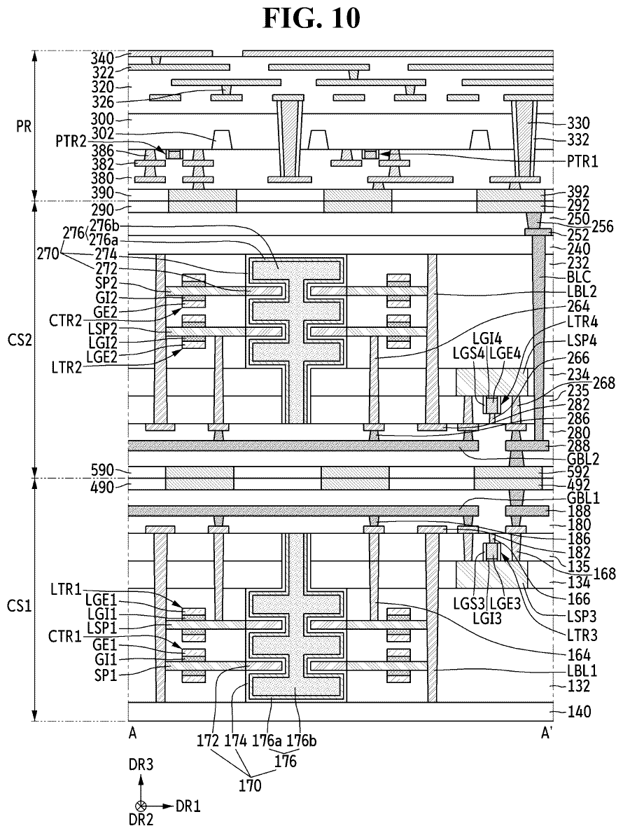

FIGS. 9 and 10 are cross-sectional views of semiconductor memory devices according to some implementations. For convenience, overlapping content with the descriptions of FIGS. 1 through 8 will be briefly described, while focusing on the differences.

Referring to FIG. 9, the semiconductor memory device according to some implementations may include a plurality of first through n-th cell structures CS1 through CSn (where n is a natural number equal to or greater than 3) stacked in the third direction DR3. The first cell structure CS1 may have the same structure as any of the first cell structures CS1 described with reference to FIGS. 1 through 8. The second through n-th cell structures CS2 through CSn may have the same structure as any of the second cell structures CS2 described with reference to FIGS. 1 through 8. Each of the second through n-th cell structures CS2 through CSn may include bitline contacts BLC.

The first through n-th cell structures CS1 through CSn may share first peripheral transistors PTR1. Global bitlines (GBL1 and GBL2) of each of the first through n-th cell structures CS1 through CSn may be electrically connected to the first peripheral transistors PTR1 via the bitline contacts BLC.

Referring to FIG. 10, in the semiconductor memory device according to some implementations, first and second cell structures CS1 and CS2 may have a chip-to-chip structure. After manufacturing the first and second cell structures CS1 and CS2, the first and second cell structures CS1 and CS2 may be bonded together to fabricate the semiconductor memory device according to some implementations.

The first cell structure CS1 may include a third bonding insulating film 490 and third bonding pads 492 within the third bonding insulating film 490. The third bonding insulating film 490 may be positioned on a first wiring insulating layer 180. The third bonding pads 492 may be electrically connected to first wirings (182 and 188) and first vias 186.

The second cell structure CS2 may include a fourth bonding insulating film 590 and fourth bonding pads 592 within the fourth bonding insulating film 590. The fourth bonding insulating film 590 may be positioned on a second wiring insulating layer 280. The fourth bonding pads 592 may be electrically connected to second wirings (282 and 288) and second vias 286.

The third bonding pads 492 and the fourth bonding pads 592 may be bonded together. As a result of the bonding, the first and second cell structures CS1 and CS2 may be electrically connected. The third bonding pads 492 and the fourth bonding pads 592 may each include various metals such as Cu, Al, or W. The third and fourth bonding insulating films 490 and 590 may also be bonded together. The third and fourth bonding insulating films 490 and 590 may each include an insulating material such as silicon oxide.

First logic transistors LTR1 and first global bitlines GBL1 may be positioned between first memory cells MC1 and the second cell structure CS2, and second logic transistors LTR2 and second global bitlines GBL2 may be positioned between second memory cells MC2 and the peripheral circuit structure PR.

The first and second cell structures CS1 and CS2 may have the same structure as their respective counterparts in FIGS. 1 through 8.

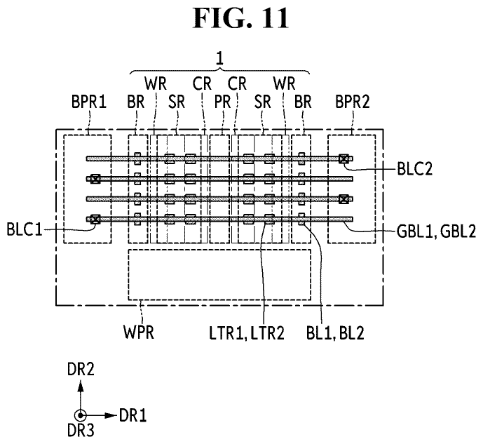

FIGS. 11 through 13 are schematic plan views of semiconductor memory devices according to some implementations. For convenience, overlapping content with the descriptions of FIGS. 1 through 10 will be briefly described, while focusing on the differences.

Referring to FIG. 11, in the semiconductor memory device according to some implementations, first and second bitline pad regions BPR1 and BPR2 may be positioned on either side of a cell region 1.

For example, the first bitline pad region BPR1, the cell region 1, and the second bitline pad region BPR2 may be arranged along the first direction DR1. The first bitline pad region BPR1 may include first bitline contacts BLC1, and the second bitline pad region BPR2 may include second bitline contacts BLC2. Adjacent first and second global bitlines GBL1 and GBL2 in the second direction DR2 may be connected to first and second bitline contacts BLC1 and BLC2, respectively. The first bitline contacts BLC1 may be arranged along the second direction DR2 within the first bitline pad region BPR1, and the second bitline contacts BLC2 may be arranged along the second direction DR2 within the second bitline pad region BPR2. For example, adjacent first global bitlines GBL1 in the second direction DR2 may be electrically connected to first and second bitline contacts BLC1 and BLC2, respectively.

FIG. 11 illustrates the cell region 1 in FIG. 1 by way of example. In some implementations, the semiconductor memory device according to some implementations may include the cell region 1 in FIG. 5.

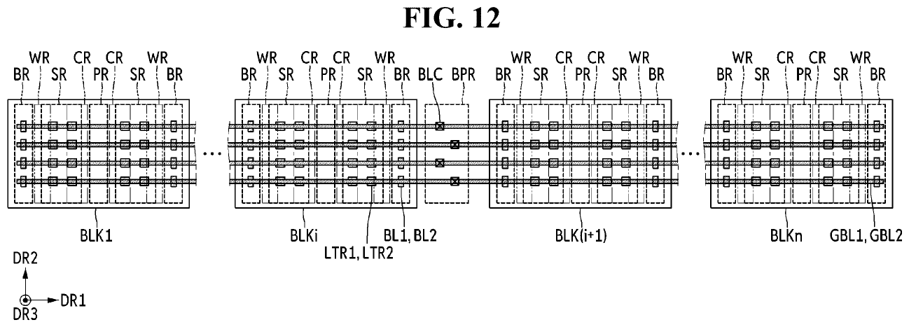

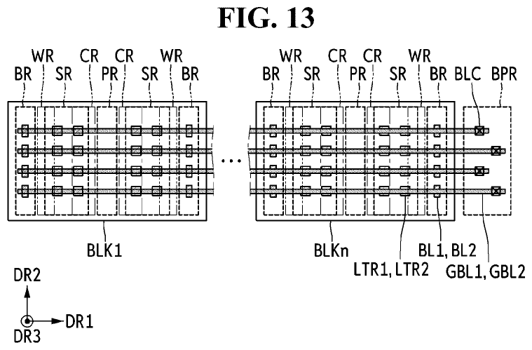

Referring to FIGS. 12 and 13, the semiconductor memory devices according to some implementations may each include first through n-th memory blocks BLK1 through BLKn (where n is a natural number and i is a natural number smaller than n). For example, the first through n-th memory blocks BLK1 through BLKn may be arranged along the first direction DR1. The first through n-th memory blocks BLK1 through BLKn may each include a first cell structure CS1, a second cell structure CS2, and a peripheral circuit structure PR described with reference to FIGS. 1 through 10.

In FIGS. 12 and 13, the first through n-th memory blocks BLK1 through BLKn are illustrated as including the cell region 1 in FIG. 1. In some implementations, the first through n-th memory blocks BLK1 through BLKn may include the cell region 1 in FIG. 5.

First global bitlines GBL1 and second global bitlines GBL2 of each of the first through n-th memory blocks BLK1 through BLKn may be connected to each other. The first global bitlines GBL1 and the second global bitlines GBL2 may extend in the first direction DR1 across the first through n-th memory blocks BLK1 through BLKn. Bitline contacts BLC may be positioned in a bitline pad region BPR. The first global bitlines GBL1 and the second global bitlines GBL2 may be electrically connected via the bitline contacts BLC.

Referring to FIG. 12, the bitline pad region BPR may be positioned between adjacent memory blocks (BLK1 through BLKn). The bitline contacts BLC may also be positioned between the adjacent memory blocks (BLK1 through BLKn). For example, the bitline pad region BPR may be positioned between the i-th memory block BLKi and the (i+1)th memory block BLK(i+1).

Referring to FIG. 13, the bitline pad region BPR may be positioned at at least one end of the array of the first through n-th memory blocks BLK1 through BLKn.

For example, the bitline pad region BPR may be positioned on one side of the n-th memory block BLKn in the first direction DR1. The bitline pad region BPR may be adjacent to the n-th memory block BLKn in the first direction DR1. In another example, the bitline pad region BPR may be positioned on one side of the first memory block BLK1 in the first direction DR1. The first memory block BLK1 may be adjacent to the bitline pad region BPR in the first direction DR1. In yet another example, bitline pad regions BPR may be positioned on either side of the array of the first through n-th memory blocks BLK1 through BLKn in the first direction DR1. That is, the array of the first through n-th memory blocks BLK1 through BLKn may be positioned between two bitline pad regions BPR. Some bitline contacts BLC may be positioned in the bitline pad region BPR adjacent to the n-th memory block BLKn, while the remaining bitline contacts BLC may be positioned in the bitline pad region BPR adjacent to the first memory block BLK1.

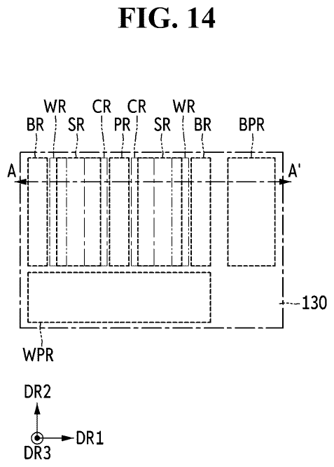

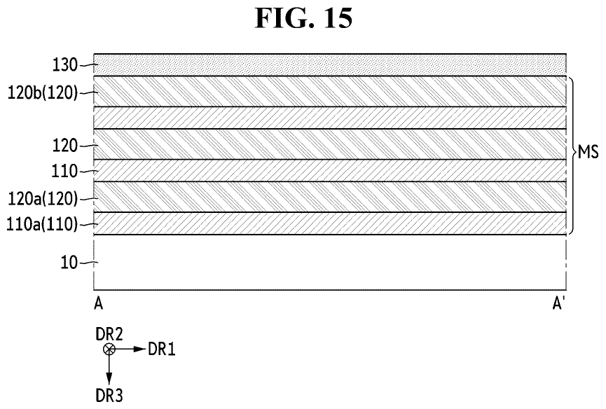

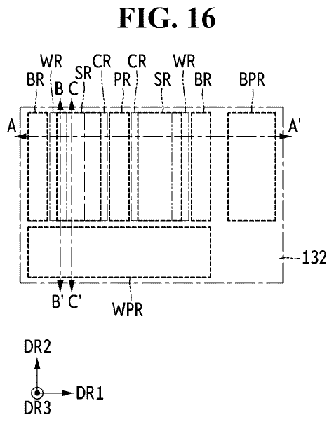

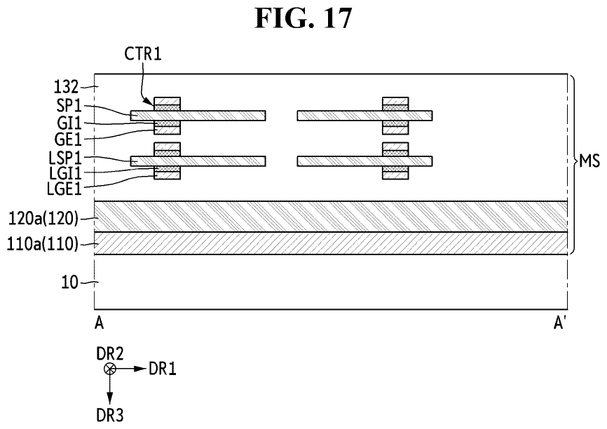

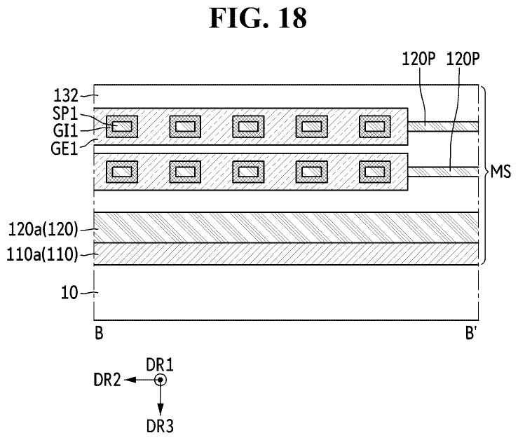

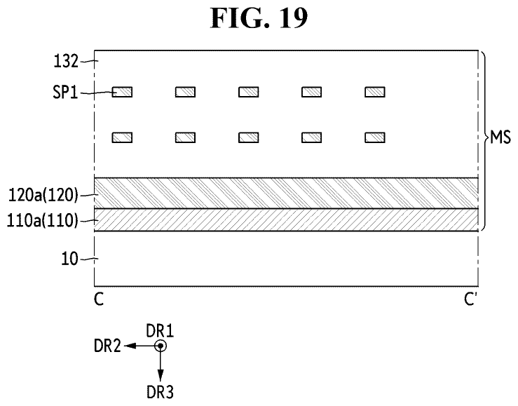

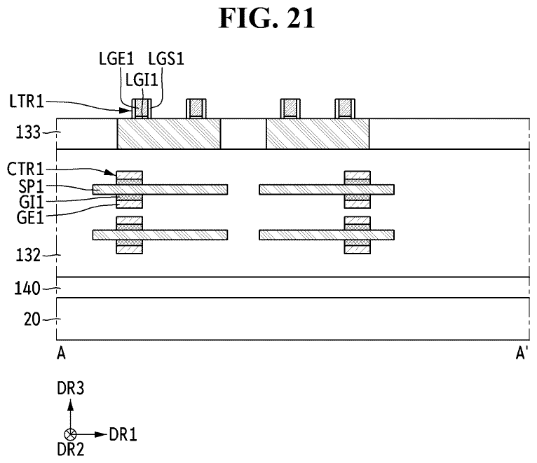

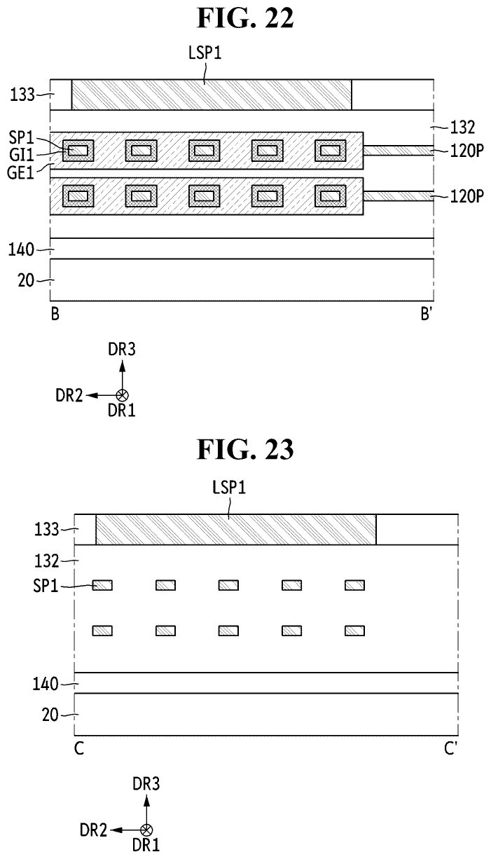

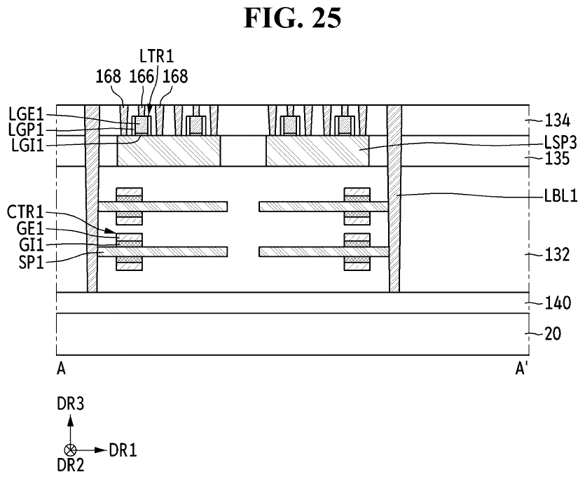

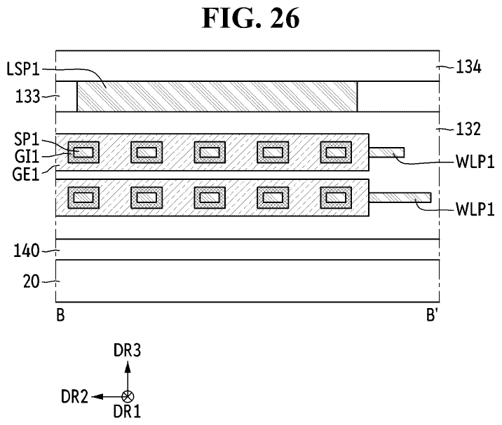

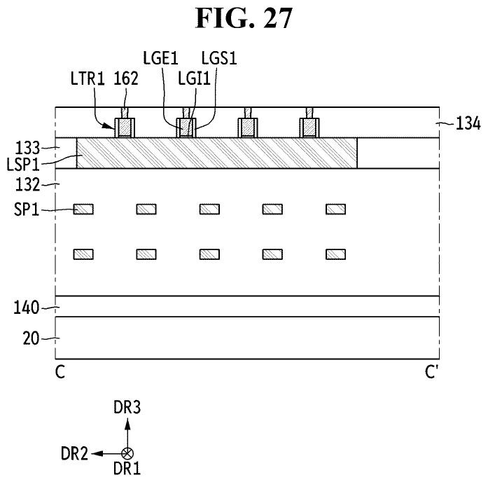

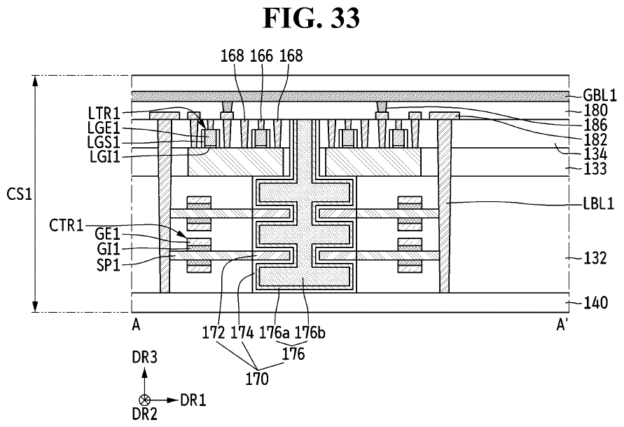

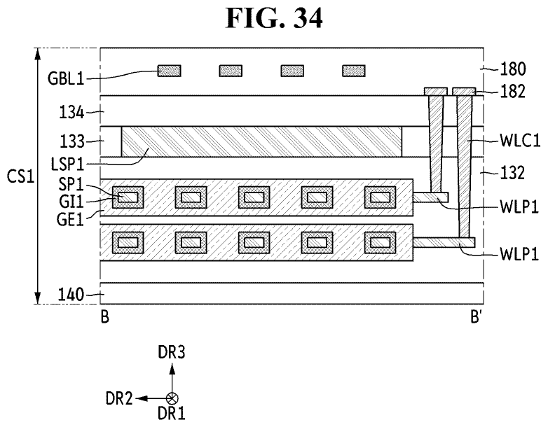

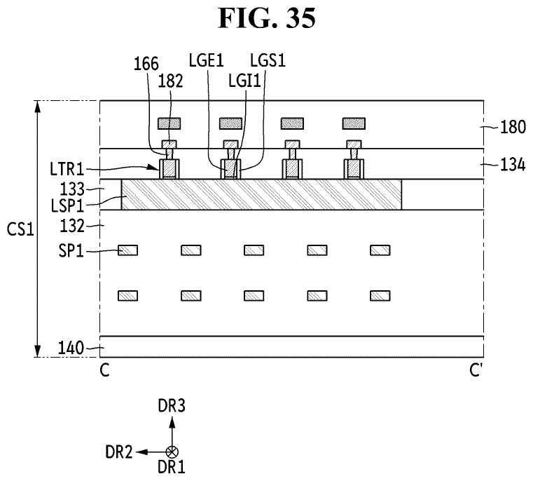

FIGS. 14 through 37 are diagrams illustrating intermediate stages of a method for manufacturing a semiconductor memory device according to some implementations. FIGS. 15, 17, 21, 25, 29, 33, and 37 are cross-sectional views taken along A-A′ of FIGS. 14, 16, 20, 24, 28, 32, and 36, respectively. FIGS. 18, 22, 26, 31, and 34 are cross-sectional views taken along B-B′ of FIGS. 16, 20, 24, 30, and 32, respectively. FIGS. 19, 23, 27, and 35 are cross-sectional views taken along C-C′ of FIGS. 16, 20, 24, and 32, respectively.

Bitline regions BR, wordline regions WR, semiconductor regions SR, capacitor regions CR, a plate region PR, and a wordline pad region WPR illustrated in FIGS. 14, 16, 20, 24, 28, 30, 32, and 36 represent planar areas where first local bitlines LBL1, first cell gate electrodes GE1, first logic semiconductor patterns LSP1, first data storage devices 170, first plate electrodes 176, and first cell gate connection pads WLP1 are to be formed in subsequent processes. A-A′ in FIGS. 14, 16, 20, 24, 28, 30, 32, and 36 may correspond to I-I′ in FIG. 1. B-B′ in FIGS. 14, 16, 20, 24, 28, 30, 32, and 36 may correspond to II-II′ in FIG. 1.

Referring to FIGS. 14 and 15, a mold structure MS is formed, including a plurality of sacrificial layers 110 and a plurality of semiconductor layers 120 alternately stacked on a substrate 10.

The substrate 10 may include bulk silicon or SOI. Alternatively, the substrate 10 may be a silicon substrate or may include other materials such as silicon germanium, gallium arsenide, silicon germanium-on-insulator (SGOI), indium antimonide, a lead telluride compound, indium arsenide, indium phosphide, gallium arsenide, or gallium antimonide. The substrate 10 may also be an epitaxial layer formed on a base substrate, a ceramic substrate, a quartz substrate, or a display glass substrate.

The sacrificial layers 110 may include a material that has etching selectivity with respect to the semiconductor layers 120. For example, the sacrificial layers 110 may include at least one of silicon germanium, silicon oxide, silicon nitride, or silicon oxynitride. The semiconductor layers 120 may include silicon, germanium, silicon germanium, or IGZO. In one example, the semiconductor layers 120 may include silicon, and the sacrificial layers 110 may include silicon germanium doped with carbon.

Thereafter, a mold insulating layer 130 is formed on the mold structure MS. The mold insulating layer 130 may include an insulating material such as silicon oxide, silicon nitride, or silicon oxynitride.

Referring to FIGS. 14 through 19, all the sacrificial layers 110 except for a lowermost sacrificial layer 110a may be removed, and all the semiconductor layers 120 except for a lowermost semiconductor layer 120a may be patterned, thereby forming first cell semiconductor patterns SP1.

For example, through a selective etching process, all the semiconductor layers 120 except for the lowermost semiconductor layer 120a may be removed. As a result, the upper and lower surfaces of all the sacrificial layers 110 except for the lowermost sacrificial layer 110a may be exposed. Thereafter, through a thinning process, the thickness of all the semiconductor layers 120 except for the lowermost semiconductor layer 120a may be reduced.

Thereafter, all the sacrificial layers 110 except for the lowermost sacrificial layer 110a may be removed, and the remaining space may be filled with an insulating material, thereby forming a first cell insulating layer 132.

Thereafter, the mold insulating layer 130 may be patterned, thereby forming first insulating pattern. Using the first insulating pattern as an etching mask, all the semiconductor layers 120 except for the lowermost semiconductor layer 120a may be patterned. First trenches, which separate all the semiconductor layers 120 except for the lowermost semiconductor layer 120a along the first direction DR1, may be formed using the first insulating pattern as an etching mask. At this time, the lowermost semiconductor layer 120a may be used as an etch stop layer. The first trenches may extend in the third direction DR3, penetrating the lowermost sacrificial layer 110a and all the semiconductor layers except for the lowermost semiconductor layer 120a.

Thereafter, the first insulating pattern may be removed, and an insulating layer covering the first interlayer insulating layer 134 may be formed. The insulating layer may be patterned, thereby forming a second insulating pattern. Using the second insulating pattern as an etching mask, all the semiconductor layers 120 except for the lowermost semiconductor layer 120a may be patterned. Second trenches, which separate the semiconductor layers 120 except for the lowermost semiconductor layer 120a along the second direction DR2, may be formed using the second insulating pattern as an etching mask. At this time, the lowermost semiconductor layer 120a may be used as an etch stop layer. The second trenches may extend in the third direction DR3, penetrating the lowermost sacrificial layer 110a and all the semiconductor layers except for the lowermost semiconductor layer 120a. Thereafter, the second insulating pattern may be removed.

Accordingly, a plurality of first cell semiconductor patterns SP1, which are spaced apart in the first and second directions DR1 and DR2 and stacked in the third direction DR3, may be formed. Remaining portions 120P of the semiconductor layers 120, except for the first cell semiconductor patterns SP1 and the lowermost semiconductor layer 120a, may later be replaced with first cell gate connection pads WLP1 in a subsequent process. The remaining portions 120P may be positioned on extension lines in the second direction DR2 of the first cell semiconductor patterns SP1. The remaining portions 120P may be located in the wordline pad region WPR.

Thereafter, through a selective etching process, the first cell insulating layer 132 surrounding the first cell semiconductor patterns SP1 may be partially removed. Thereafter, first cell gate insulating films GI1 surrounding portions of the first cell semiconductor patterns SP1 may be formed by a deposition process. The first cell gate insulating films GI1 may be formed using, for example, an atomic layer deposition (ALD) process or a chemical vapor deposition (CVD) process.

Thereafter, first cell gate electrodes GE1 covering the first cell gate insulating films GI1 may be formed. For example, through a CVD process, the first cell gate electrodes GE1 may be formed to fill the spaces remaining after the removal of the first interlayer insulating layer 134 through the selective etching process. Accordingly, first cell transistors CTR1, including the first cell gate electrodes GE1 and the first cell semiconductor patterns SP1, may be formed.

The first cell gate electrodes GE1 may have a line shape extending in the second direction DR2. The first cell gate electrodes GE1 may surround the first cell semiconductor patterns SP1 arranged along the second direction DR2. The first cell gate electrodes GE1 may be spaced apart from the first cell gate electrodes GE1 by the first cell gate insulating films GI1. The first cell gate electrodes GE1 may be positioned in the wordline regions WR.

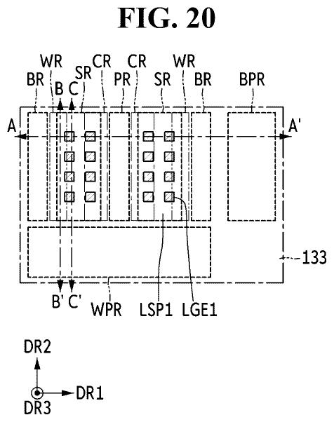

Referring to FIGS. 20 through 23, a first insulating layer 140 may be formed on the mold structure MS. A carrier substrate 20 may be attached to the first insulating layer 140. The carrier substrate 20, the mold structure MS, and the substrate 10 may be flipped upside down. That is, the substrate 10 may be positioned at the top, and the carrier substrate 20 may be positioned at the bottom. Thereafter, the substrate 10 and the lowermost sacrificial layer 110a may be removed.

Thereafter, the lowermost semiconductor layer 120a may be patterned, thereby forming first logic semiconductor patterns LSP1. For example, photoresist patterns may be formed on the lowermost semiconductor layer 120a through exposure and development processes, and an etching process may be performed using the photoresist patterns as an etching mask, thereby forming third trenches penetrating the lowermost semiconductor layer 120a in the third direction DR3. An insulating material may be filled into the third trenches, thereby forming first insulating patterns 133. The first insulating patterns 133 may serve as element isolation patterns. The first insulating patterns 133 may define the first logic semiconductor patterns LSP1. The first logic semiconductor patterns LSP1 may be positioned in the semiconductor regions SR.

Thereafter, first logic gate electrodes LGE1, first logic gate insulating films LGI1, and first gate spacers LGS1 may be formed on the first logic semiconductor patterns LSP1. The first logic gate insulating films LGI1 may be formed on the first logic semiconductor patterns LSP1. The first logic gate electrodes LGE1 may be formed on the first logic gate insulating films LGI1. The first gate spacers LGS1 may be formed on both side surfaces of the first logic gate electrodes LGE1 and both side surfaces of the first logic gate insulating films LGI1. Impurities may be doped into the first logic semiconductor patterns LSP1 on both sides of the first logic gate electrodes LGE1, thereby forming first source/drain regions and second source/drain regions. Accordingly, first logic transistors LTR1, including the first logic gate insulating films LGI1, the first logic semiconductor patterns LSP1, the first logic gate electrodes LGE1, the first gate spacers LGS1, and the first source/drain regions and second source/drain regions, may be formed.

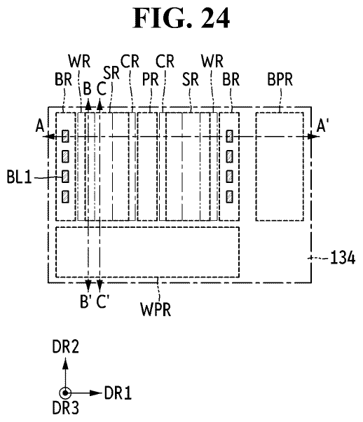

Referring to FIGS. 24 through 27, a first interlayer insulating layer 134 covering the first logic gate electrodes LGE1, the first logic semiconductor patterns LSP1, and the first insulating patterns 133 may be formed. The first interlayer insulating layer 134 may cover the first logic gate electrodes GE1, the first gate spacers LGS1, the first logic semiconductor patterns LSP1, and the first insulating patterns 133.

Thereafter, first logic gate contacts 162 and first source/drain contacts 164 penetrating the first interlayer insulating layer 134 may be formed. For example, contact holes penetrating the first interlayer insulating layer 134 may be formed, and a metal material may be filled into the contact holes, thereby forming the first logic gate contacts 162 and the first source/drain contacts 164. The first logic gate contacts 162 may penetrate the first interlayer insulating layer 134 to be in contact with the upper surfaces of the first logic gate electrodes LGE1. The first source/drain contacts 164 may penetrate the first interlayer insulating layer 134 to be in contact with the upper surfaces of the first logic semiconductor patterns LSP1 on both sides of the first logic gate electrodes LGE1. The first source/drain contacts 164 may be connected to the first source/drain regions and second source/drain regions.

Thereafter, fourth trenches may be formed to penetrate the first interlayer insulating layer 134, the first insulating patterns 133, and the first cell insulating layer 132. The fourth trenches may be formed by an etching process in the third direction DR3, and during the etching process, the first insulating layer 140 may be used as an etch stop layer. As the fourth trenches are formed, first ends of the first cell semiconductor patterns SP1 may be exposed. For example, first ends of the first cell semiconductor patterns SP1 in the first direction DR1 may be exposed. Impurities may be doped into the surfaces of the exposed first ends of the first cell semiconductor patterns SP1 in the first direction DR1.

Thereafter, a conductive material may be filled into the fourth trenches, thereby forming first local bitlines LBL1. The first local bitlines LBL1 may be in contact with the first ends of the first cell semiconductor patterns SP1. The first local bitlines LBL1 may have a pillar shape extending in the third direction DR3. Multiple first cell semiconductor patterns SP1 stacked in the third direction DR3 may be connected to a single first local bitline LBL1.

The first local bitlines LBL1 may be formed in the bitline regions BR in FIG. 24. The first local bitlines LBL1 are illustrated as having a rectangular planar shape. In some implementations, the planar shape of the first local bitlines LBL1 may be a circle, an ellipse, or another polygon.

Thereafter, remaining portions 120P of the semiconductor layer 120 located in the same layers as the first cell semiconductor patterns SP1 may be replaced with a conductive material, thereby forming a plurality of first cell gate connection pads WLP1 connected to the respective first cell gate electrodes GE1. The first cell gate connection pads WLP1 may be connected to the first cell gate electrodes GE1 in the second direction DR2. The first cell gate connection pads WLP1 may be positioned in the wordline pad region WPR in FIG. 24.

The first cell gate connection pads WLP1 may have a stepped structure. For example, the length of the first cell gate connection pads WLP1 in the second direction DR2 may increase in a direction toward the first insulating layer 140.

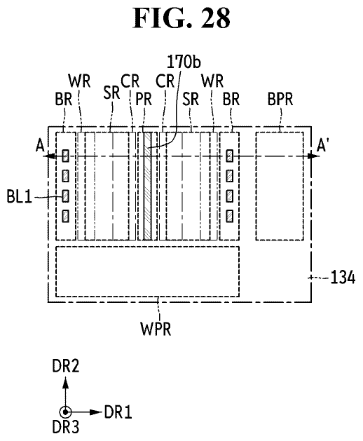

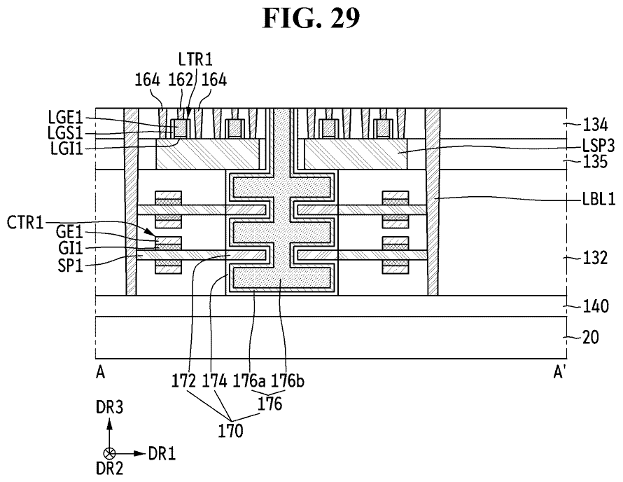

Referring to FIGS. 28 and 29, fifth trenches penetrating the first interlayer insulating layer 134, the first insulating patterns 133, and the first cell insulating layer 132 may be formed, and a plurality of data storage devices 170 may be formed through the fifth trenches. The fifth trenches may be formed by etching the first interlayer insulating layer 134, the first insulating patterns 133, and the first cell insulating layer 132 in the third direction DR3. At this time, the first insulating layer 140 may be used as an etch stop layer. The bottom surfaces of the fifth trenches may be defined by the upper surface of the first insulating layer 140. The sidewalls of the fifth trenches may be defined by the side surfaces of the first interlayer insulating layer 134, the first insulating patterns 133, the first cell insulating layer 132, and the first cell semiconductor patterns SP1. The first cell semiconductor patterns SP1 may be exposed through the fifth trenches.

Thereafter, portions of the first cell semiconductor patterns SP1 exposed through the fifth trenches may be etched, thereby forming a plurality of first recesses. The first recesses may be formed by etching the first cell semiconductor patterns SP1 in the first direction DR1. As the first recesses are formed, the second ends of the first cell semiconductor patterns SP1 in the first direction DR1 may be exposed. Impurities may be doped into the surfaces of the exposed second ends of the first cell semiconductor patterns SP1 through the first recesses.

Thereafter, a conductive material may be filled into the first recesses, thereby forming a plurality of first electrodes 172. The first electrodes 172 may be in contact with opposite ends of the respective first cell semiconductor patterns SP1. The first electrodes 172 may be connected to the respective first cell semiconductor patterns SP1 in the first direction DR1.

Thereafter, portions of the first cell insulating layer 132 exposed through the fifth trenches may be etched, thereby forming a plurality of second recesses. Some of the second recesses may each have sidewalls defined by the opposing surfaces of adjacent first electrodes 172 in the third direction DR3 and a bottom surface defined by the side surfaces of the first cell insulating layer 132. Other second recesses may each have sidewalls defined by the upper surfaces of the first electrodes 172, the lower surfaces of the first logic semiconductor patterns LSP1, and the lower surfaces of the first insulating patterns 133, and a bottom surface defined by the side surfaces of the first cell insulating layer 132. Still other second recesses may each have sidewalls defined by the lower surfaces of the first electrodes 172 and the upper surface of the first insulating layer 140, and a bottom surface defined by the side surfaces of the first cell insulating layer 132. The second recesses may be formed by etching the first cell insulating layer 132 in the first direction DR1 at locations between the first cell semiconductor patterns SP1, between the uppermost first cell semiconductor patterns SP1 and the first logic semiconductor patterns LSP1, and between the lowermost first cell semiconductor patterns SP1 and the first insulating layer 140.

Thereafter, first dielectric layers 174 and first conductive layers 176a may be formed to cover the sidewalls and bottom surfaces of the second recesses and the sidewalls and bottom surface of the fifth trench. The first dielectric layers 174 may extend along the fifth trenches and the second recesses. The first conductive layers 176a may be formed along the first dielectric layers 174.

Thereafter, the remaining spaces in the second recesses and the remaining spaces in the fifth trenches may be filled with a conductive material, thereby forming second conductive layers 176b. Accordingly, first plate electrodes 176, including the first conductive layers 176a and the second conductive layers 176b, may be formed. A plurality of data storage devices 170, including the first electrodes 172, the first dielectric layers 174, and the first plate electrodes 176, may be formed. The first plate electrodes 176 may be positioned in the plate region PR. The first electrodes 172, the first dielectric layers 174, and portions of the first plate electrodes 176 between adjacent first electrodes 172 may be positioned in the capacitor region CR.

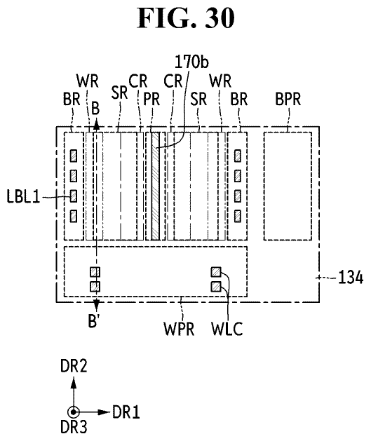

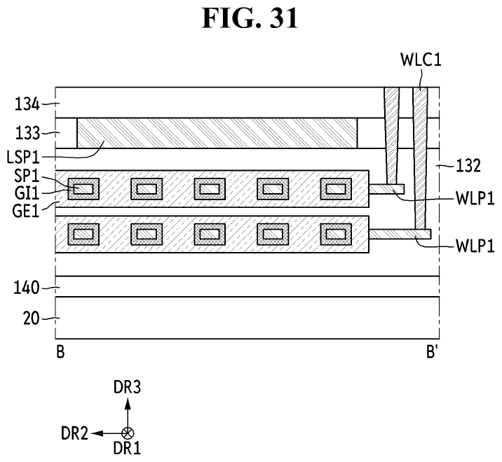

Referring to FIGS. 30 and 31, a plurality of sixth trenches penetrating the first interlayer insulating layer 134, the first insulating patterns 133, and the first cell insulating layer 132 may be formed. The sixth trenches may be formed by an etching process in the third direction DR3 that penetrates the first interlayer insulating layer 134, the first insulating patterns 133, and the first cell insulating layer 132. At this time, the first cell gate connection pads WLP1 may be used as an etch stop layer.

Thereafter, a conductive material may be filled into the sixth trenches, thereby forming a plurality of first cell gate contacts WLC1. The first cell gate contacts WLC1 may be in contact with the upper surfaces of the respective first cell gate connection pads WLP1. The first cell gate connection pads WLP1 may be connected to the respective first cell gate electrodes GE1 stacked in the third direction DR3. The first cell gate contacts WLC1 may have a pillar shape extending in the third direction DR3.

The first cell gate contacts WLC1 may be positioned in the wordline pad region WPR. The first cell gate contacts WLC1 are illustrated as having a rectangular planar shape. In some implementations, the planar shape of the first cell gate contacts WLC1 may be a circle, an ellipse, or another polygon.

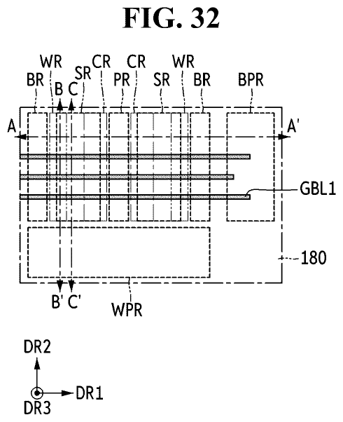

Referring to FIGS. 32 through 35, first wirings 182 and first global bitlines GBL1 may be formed on the first interlayer insulating layer 134. For example, a first wiring insulating layer 180 may be formed on the first interlayer insulating layer 134, and the first wiring insulating layer 180 may be patterned and then filled with a conductive material, thereby forming a plurality of first wirings 182, a plurality of first vias 186, and the first global bitlines GBL1. The first wirings 182 may each include multiple layers, and the first vias 186 may connect first wirings 182 positioned at different heights. The first wirings 182 and the first vias 186 may be electrically connected to the first global bitlines GBL1, the first local bitlines LBL1, the first cell gate contacts WLC1, the first plate electrodes 176 of the data storage devices 170, the first logic gate contacts 166, and the first source/drain contacts 168.

The first wirings 182 may connect the first global bitlines GBL1 and the first local transistors LTR1 and may connect the first local bitlines LBL1 and the first local transistors LTR1. The first wirings 182 may each connect one of a pair of first source/drain contacts 168 connected to a pair of source/drain regions of a first local transistor LTR1 to one first global bitline GBL1, and may connect the other first source/drain contact 168 to one first local bitline LBL1. That is, the first local transistors LTR1 may be connected between the first global bitlines GBL1 and the first local bitlines LBL1.

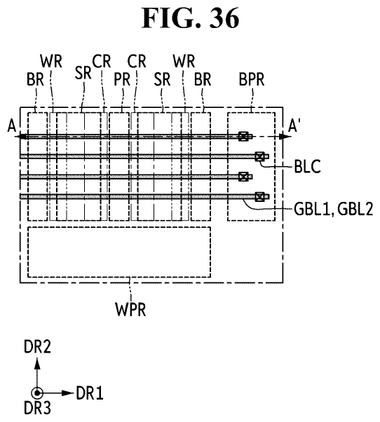

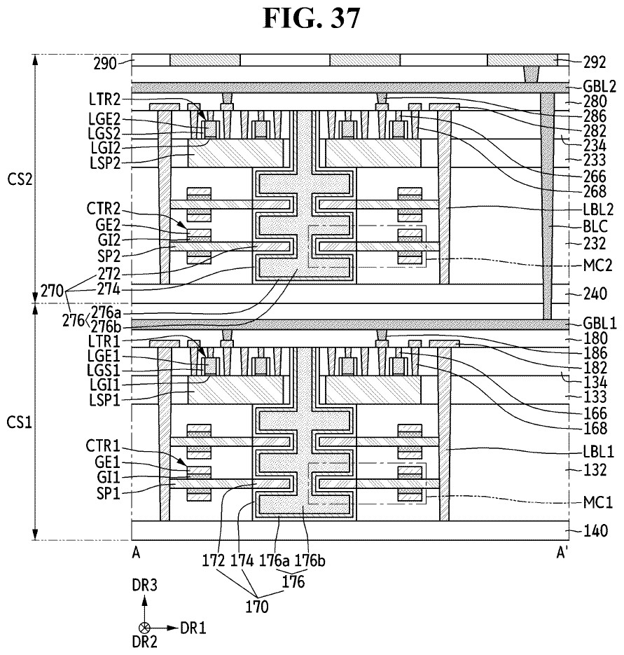

Referring to FIGS. 36 and 37, a second cell structure CS2 may be bonded to the first cell structure CS1.

For example, according to the method described with reference to FIGS. 14 through 35, the second cell structure CS2, including the second insulating layer 240, the second local bitlines LBL2, the second memory cells MC2, the second logic transistors LTR2, the second logic gate contacts 266, the second source/drain contacts 268, the second wiring insulating layer 280, and the second wirings 282, may be formed on the carrier substrate 20. That is, a portion of the second cell structure CS2 may be formed on the carrier substrate 20. Then, the carrier substrate 20 may be removed, and the portion of the second cell structure CS2 may be bonded. The second insulating layer 240 may be in contact with the first wiring insulating layer 180. Accordingly, the second cell structure CS2 may be bonded to the first cell structure CS1. Thereafter, bitline contacts BLC, first global bitlines GLB2, second vias 286, a second wiring insulating layer 280, a first bonding insulating film 290, and first bonding pads 292 may be formed. Consequently, a second cell structure CS2 may be formed.

Thereafter, referring again to FIGS. 1 and 2, a peripheral circuit structure PR may be bonded onto the second cell structure CS2. The first bonding insulating film 290 and the first bonding pads 292 of the second cell structure CS2 may be bonded to a second bonding insulating film 390 and second bonding pads 392, respectively, of the peripheral circuit structure PR.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present disclosure have been described with reference to the accompanying drawings, the present disclosure is not limited to these implementations and may be manufactured in various other forms. Those skilled in the art will understand that the technical scope or essential characteristics of the present disclosure can be modified and implemented in other specific forms without departing from the spirit of the invention. Therefore, the implementations described above should be understood as being illustrative in all respects and not limiting.

What is claimed is:

1. A semiconductor memory device comprising:
a first cell structure comprising (i) a plurality of first local bitlines extending in a vertical direction, (ii) a plurality of first memory cells connected to the plurality of first local bitlines, respectively, and arranged in the vertical direction, (iii) a plurality of first local bitline multiplexers connected to the plurality of first local bitlines, respectively, and (iv) a plurality of first global bitlines connected to the plurality of first local bitline multiplexers, respectively;
a second cell structure on the first cell structure and comprising (i) a plurality of second local bitlines extending in the vertical direction, (ii) a plurality of second memory cells connected to the plurality of second local bitlines, respectively, and arranged in the vertical direction, (iii) a plurality of second local bitline multiplexers connected to the plurality of second local bitlines, respectively, and (iv) a plurality of second global bitlines connected to the second local bitline multiplexers, respectively;
a plurality of bitline contacts extending into the second cell structure and connecting the plurality of first global bitlines with the plurality of second global bitlines, respectively; and
a peripheral circuit structure on the second cell structure and comprising a sense amplifier connected to the plurality of bitline contacts,
wherein the plurality of first global bitlines and the plurality of second global bitlines are connected to the sense amplifier.

2. The semiconductor memory device of claim 1, wherein the first cell structure comprises a plurality of first global bitline multiplexers connected to the plurality of first global bitlines, respectively,
wherein the second cell structure comprises a plurality of second global bitline multiplexers connected to the plurality of second global bitlines, respectively, and
wherein the plurality of bitline contacts connect the plurality of first global bitline multiplexers with the plurality of second global bitline multiplexers, respectively.

3. The semiconductor memory device of claim 1, wherein the first cell structure and the second cell structure define a cell region and a bitline pad region adjacent to the cell region in a first horizontal direction,
wherein the first global bitlines and the second global bitlines extend in the first horizontal direction in the cell region and the bitline pad region, and
wherein each of the plurality of bitline contacts alternately offsets from adjacent bitline contact along a second horizontal direction in the bitline pad region.

4. The semiconductor memory device of claim 1, wherein the first cell structure and the second cell structure comprise a plurality of memory blocks arranged in a horizontal direction, each memory block comprising the plurality of first local bitlines, at least one of the plurality of first local bitline multiplexers, the plurality of first global bitlines, the plurality of second local bitlines, at least one of the plurality of second local bitline multiplexers, and the plurality of second global bitlines,
wherein the plurality of first global bitlines and the plurality of second global bitlines extend in the horizontal direction across the plurality of memory blocks, and
wherein the plurality of bitline contacts are between adjacent memory blocks.

5. The semiconductor memory device of claim 1, wherein the first cell structure and the second cell structure define a first bitline pad region, a cell region, and a second bitline pad region that are sequentially arranged along a horizontal direction,
wherein the plurality of first global bitlines and the plurality of second global bitlines extend in the horizontal direction across the first bitline pad region, the cell region, and the second bitline pad region, and
wherein the plurality of bitline contacts comprise a plurality of first bitline contacts in the first bitline pad region and a plurality of second bitline contacts in the second bitline pad region.

6. The semiconductor memory device of claim 1, wherein the first cell structure and the second cell structure comprise memory blocks arranged in a horizontal direction, and
wherein the plurality of bitline contacts are between adjacent memory blocks.

7. A semiconductor memory device comprising:
a first cell structure comprising (i) a first local bitline extending in a vertical direction on a first insulating layer, (ii) a plurality of first cell semiconductor patterns arranged in the vertical direction, each first cell semiconductor pattern having a first end connected to the first local bitline, (iii) a plurality of first data storage devices connected to second ends of the plurality of first cell semiconductor patterns, (iv) a plurality of first cell gate electrodes on the plurality of first cell semiconductor patterns, (v) a first logic semiconductor pattern spaced apart in the vertical direction from the plurality of first cell semiconductor patterns, (vi) a first logic transistor on the first logic semiconductor pattern and connected to the first local bitline, and (vii) a first global bitline connected to the first logic transistor;
a second cell structure comprising (i) a second local bitline extending in the vertical direction on a second insulating layer, (ii) a plurality of second cell semiconductor patterns arranged in the vertical direction, each second cell semiconductor pattern having a first end connected to the second local bitline, (iii) a plurality of second data storage devices connected to second ends of the plurality of second cell semiconductor patterns, (iv) a plurality of second cell gate electrodes on the second cell semiconductor patterns, (v) a second logic semiconductor pattern spaced apart in the vertical direction from the plurality of second cell semiconductor patterns, (vi) a second logic transistor on the second logic semiconductor pattern and connected to the second local bitline, and (vii) a second global bitline connected to the second logic transistor;
a bitline contact extending into the second cell structure and connected to the first global bitline and the second global bitline; and
a peripheral circuit structure comprising a peripheral circuit substrate and a peripheral circuit transistor on the peripheral circuit substrate, the peripheral circuit transistor being connected to the first global bitline and the second global bitline.

8. The semiconductor memory device of claim 7, wherein the first cell structure comprises a first cell insulating layer between the first cell semiconductor patterns,
wherein the second cell structure comprises a second cell insulating layer between adjacent second cell semiconductor patterns,
wherein the first logic semiconductor pattern is on the first cell insulating layer, and
wherein the second logic semiconductor pattern and the second logic transistor are on the second insulating layer.

9. The semiconductor memory device of claim 8, wherein the first cell structure comprises a third logic semiconductor pattern on the first cell insulating layer and a third logic transistor on the third logic semiconductor pattern,
the second cell structure comprises a fourth logic semiconductor pattern on the second insulating layer and a fourth logic transistor on the fourth logic semiconductor pattern,
the third logic transistor is connected to the first global bitline and the bitline contact, and
the fourth logic transistor is connected to the second global bitline and the bitline contact.

10. The semiconductor memory device of claim 9, wherein the fourth logic semiconductor pattern and the fourth logic transistor are between the second local bitline and the bitline contact.

11. The semiconductor memory device of claim 7, wherein a first end of the first logic semiconductor pattern is connected to the first local bitline,
wherein a second end of the first logic semiconductor pattern is connected to the plurality of first data storage devices,
wherein a first end of the second logic semiconductor pattern is connected to the second local bitline, and
wherein a second end of the second logic semiconductor pattern is connected to the plurality of second data storage devices.

12. The semiconductor memory device of claim 7, wherein a first end of the first logic semiconductor pattern is connected to the first local bitline,
wherein a second end of the first logic semiconductor pattern is spaced apart from the plurality of first data storage devices,
wherein a first end of the second logic semiconductor pattern is connected to the second local bitline, and
wherein a second end of the second logic semiconductor pattern is spaced apart from the plurality of second data storage devices.

13. The semiconductor memory device of claim 7, wherein the first cell structure comprises (i) a first cell insulating layer on the first insulating layer and between adjacent first cell semiconductor patterns, and (ii) another first cell insulating layer on the first cell insulating layer and covering the first global bitline,
wherein the second cell structure comprises (i) a second cell insulating layer on the second insulating layer and between adjacent second cell semiconductor patterns, (ii) another second cell insulating layer on the second cell insulating layer and covering the second global bitline, (iii) a first bonding insulating film on the second cell insulating layer, and (iv) a first bonding pad within the first bonding insulating film,
wherein the peripheral circuit structure comprises a second bonding insulating film and a second bonding pad within the second bonding insulating film,
wherein the first cell insulating layer is in contact with the second insulating layer,
wherein the first bonding insulating film is in contact with the second bonding insulating film, and
wherein the first bonding pad is in contact with the second bonding pad.

14. The semiconductor memory device of claim 7, wherein the first cell structure comprises (i) a first cell insulating layer on the first insulating layer and between adjacent first cell semiconductor patterns, (ii) another first cell insulating layer on the first cell insulating layer and covering the first global bitline, (iii) a first bonding insulating film on the first cell insulating layer, and (iv) a first bonding pad within the first bonding insulating film,
wherein the second cell structure comprises (i) a second cell insulating layer on the second insulating layer and between adjacent second cell semiconductor patterns, (ii) another second cell insulating layer on the second cell insulating layer and covering the second global bitline, (iii) a second bonding insulating film on the second cell insulating layer, (iv) a second bonding pad within the second bonding insulating film, (v) a third bonding insulating film on the second insulating layer, and (vi) a third bonding pad within the third bonding insulating film,
wherein the peripheral circuit structure comprises a fourth bonding insulating film and a fourth bonding pad within the fourth bonding insulating film,
wherein the first bonding insulating film is in contact with the second bonding insulating film,
wherein the first bonding pad is in contact with the second bonding pad,
wherein the third bonding insulating film is in contact with the fourth bonding insulating film, and
wherein the third bonding pad is in contact with the fourth bonding pad.

15. A semiconductor memory device comprising:
a first cell structure comprising (i) a plurality of first local bitlines extending in a vertical direction, (ii) a plurality of first memory cells arranged in the vertical direction and connected to the plurality of first local bitlines, respectively, (iii) a plurality of first global bitlines on the plurality of first memory cells, (iv) a plurality of first local bitline multiplexers connected to the plurality of first global bitlines and the plurality of first local bitlines, respectively, and (v) a plurality of first global bitline multiplexers connected to the plurality of first global bitlines, respectively;
a second cell structure comprising (i) a plurality of second local bitlines extending in the vertical direction, (ii) a plurality of second memory cells arranged in the vertical direction and connected to the plurality of second local bitlines, respectively, (iii) a plurality of second global bitlines on the second memory cells, (iv) a plurality of second local bitline multiplexers connected to the plurality of second global bitlines and the plurality of second local bitlines, respectively, and (v) a plurality of second global bitline multiplexers connected to the plurality of the second global bitlines, respectively; and
a peripheral circuit structure on the second cell structure and comprising a sense amplifier connected to the plurality of first global bitlines and the plurality of second global bitlines.

16. The semiconductor memory device of claim 15, wherein the plurality of first local bitline multiplexers overlap the plurality of first memory cells in the vertical direction,
the plurality of second local bitline multiplexers overlap the plurality of second memory cells in the vertical direction,
the plurality of first global bitline multiplexers are offset from the plurality of first memory cells in the vertical direction, and
the second global bitline multiplexers are offset from the plurality of second memory cells in the vertical direction.

17. The semiconductor memory device of claim 15, wherein the plurality of first global bitline multiplexers are positioned at a height different from the plurality of first local bitline multiplexers, and
wherein the plurality of second global bitline multiplexers are positioned at a height different from the plurality of second local bitline multiplexers.

18. The semiconductor memory device of claim 15, wherein the plurality of first global bitline multiplexers are positioned at a same height as the plurality of first local bitline multiplexers, and
wherein the plurality of second global bitline multiplexers are positioned at a same height as the plurality of second local bitline multiplexers.

19. The semiconductor memory device of claim 15, wherein the plurality of first local bitline multiplexers and the plurality of first global bitline multiplexers are between (i) the plurality of first memory cells and (ii) the second cell structure, and
the plurality of second local bitline multiplexers and the plurality of second global bitline multiplexers are between (i) the plurality of second memory cells and (ii) the peripheral circuit structure.

20. The semiconductor memory device of claim 15, wherein the plurality of first local bitline multiplexers and the plurality of first global bitline multiplexers are between (i) the plurality of first memory cells and (ii) the second cell structure, and
wherein the plurality of second local bitline multiplexers and the plurality of second global bitline multiplexers are between (i) the first cell structure and (ii) the plurality of second memory cells.
